(19) United States
(12) Patent Application Publication
(10) Pub. No.: US 2022/0278062 A1
(43) Pub. Date: Sep. 1, 2022

(54) SEMICONDUCTOR DEVICE AND METHOD OF MANUFACTURING THE SAME

(71) Applicant: Kioxia Corporation, Tokyo (JP)

(72) Inventor: Takeshi MATSUNAGA, Yokohama (JP)

(73) Assignee: Kioxia Corporation, Tokyo (JP)

(21) Appl. No.: 17/400,653

(22) Filed: Aug. 12, 2021

(30) Foreign Application Priority Data
Feb. 26, 2021 (JP) 2021-030397

(51) Int. Cl. H01L 23/00; H01L 25/065; H01L 27/11556; H01L 27/11582; H01L 21/78

(52) U.S. Cl. CPC H01L 24/06; H01L 25/0657; H01L 27/11556; H01L 27/11582; H01L 21/78; H01L 24/03; H01L 24/80

(57) ABSTRACT

A semiconductor device comprises a first chip and a second chip bonded via a plurality of bonding electrodes. The first chip comprises: a first substrate; a first semiconductor element; and a first bonding electrode which is one of the plurality of bonding electrodes and is electrically connected to the first semiconductor element. The second chip comprises: a second substrate; a second semiconductor element; and a second bonding electrode which is one of the plurality of bonding electrodes and is electrically connected to the second semiconductor element. The second substrate comprises: a pair of first regions which are provided in both end portions; and a pair of second regions which are provided in both end portions. Viewed from a third direction, portions provided in the first region and the second region of the second substrate do not overlap the first substrate.

### CROSS-REFERENCE TO RELATED APPLICATIONS

This application is based upon and claims the benefit of Japanese Patent Application No. 2021-030397, filed on Feb. 26, 2021, the entire contents of which are incorporated herein by reference.

### BACKGROUND

### Field

Embodiments herein relate to a semiconductor device and a method of manufacturing the same.

### Description of the Related Art

There is known technology for forming a plurality of bonding electrodes on two wafers, bonding these two wafers via these plurality of bonding electrodes, and dicing these two wafers by the likes of a dicing blade, thereby forming a plurality of dies.

### BRIEF DESCRIPTION OF THE DRAWINGS

FIG. 1 is a schematic block diagram showing a configuration of a semiconductor memory device according to a first embodiment.

FIG. 2 is a schematic side view showing a configuration of same semiconductor memory device.

FIG. 3 is a schematic plan view showing a configuration of same semiconductor memory device.

FIG. 4 is a schematic exploded perspective view showing a configuration of same semiconductor memory device.

FIG. 5 is a schematic bottom view showing a configuration of same semiconductor memory device.

FIG. 6 is a schematic bottom view showing a configuration of same semiconductor memory device.

FIG. 7 is a schematic cross-sectional view showing a configuration of same semiconductor memory device.

FIG. 8 is a schematic cross-sectional view showing a configuration of same semiconductor memory device.

FIG. 9 is a schematic bottom view for explaining a method of manufacturing a semiconductor memory device according to the first embodiment.

FIG. 10 is a schematic cross-sectional view for explaining same method of manufacturing.

FIG. 11 is a schematic cross-sectional view for explaining same method of manufacturing.

FIG. 12 is a schematic cross-sectional view for explaining same method of manufacturing.

FIG. 13 is a schematic plan view for explaining same method of manufacturing.

FIG. 14 is a schematic cross-sectional view for explaining same method of manufacturing.

FIG. 15 is a schematic cross-sectional view for explaining same method of manufacturing.

FIG. 16 is a schematic cross-sectional view for explaining same method of manufacturing.

FIG. 17 is a schematic cross-sectional view for explaining same method of manufacturing.

FIG. 18 is a schematic cross-sectional view for explaining same method of manufacturing.

FIG. 19 is a schematic cross-sectional view for explaining same method of manufacturing.

FIG. 20 is a schematic cross-sectional view for explaining same method of manufacturing.

FIG. 21 is a schematic cross-sectional view for explaining same method of manufacturing.

FIG. 22 is a schematic cross-sectional view for explaining a method of manufacturing a semiconductor memory device according to a comparative example.

FIG. 23 is a schematic cross-sectional view for explaining the method of manufacturing a semiconductor memory device according to the comparative example.

FIG. 24 is a schematic cross-sectional view showing a configuration of a semiconductor memory device according to a second embodiment.

FIG. 25 is a schematic cross-sectional view for explaining a method of manufacturing a semiconductor memory device according to the second embodiment.

FIG. 26 is a schematic cross-sectional view for explaining same method of manufacturing.

FIG. 27 is a schematic cross-sectional view for explaining same method of manufacturing.

FIG. 28 is a schematic cross-sectional view for explaining same method of manufacturing.

FIG. 29 is a schematic cross-sectional view for explaining same method of manufacturing.

FIG. 30 is a schematic cross-sectional view showing a configuration of a semiconductor memory device according to a third embodiment.

FIG. 31 is a schematic cross-sectional view for explaining a method of manufacturing a semiconductor memory device according to the third embodiment.

FIG. 32 is a schematic cross-sectional view for explaining same method of manufacturing.

FIG. 33 is a schematic cross-sectional view for explaining same method of manufacturing.

FIG. 34 is a schematic cross-sectional view for explaining another method of manufacturing a semiconductor memory device according to the third embodiment.

FIG. 35 is a schematic cross-sectional view for explaining same method of manufacturing.

FIG. 36 is a schematic cross-sectional view for explaining same method of manufacturing.

FIG. 37 is a schematic cross-sectional view for explaining a modified example of the semiconductor memory device according to the third embodiment.

FIG. 38 is a schematic cross-sectional view showing a configuration of a modified example of the semiconductor memory device according to the first embodiment.

### DETAILED DESCRIPTION

A semiconductor device according to an embodiment comprises a first chip and a second chip bonded via a plurality of bonding electrodes. The first chip comprises: a first substrate; a first semiconductor element; and a first bonding electrode which is one of the plurality of bonding electrodes and is electrically connected to the first semiconductor element. The second chip comprises: a second substrate; a second semiconductor element; and a second bonding electrode which is one of the plurality of bonding electrodes and is electrically connected to the second semiconductor element. The second substrate comprises: a pair of first regions which are provided in both end portions in a first direction and extend in a second direction intersecting with the first direction; and a pair of second regions which are provided in both end portions in the second direction and extend in the first direction. Viewed from a third direction intersecting with a surface of the second substrate, portions provided in the first region and the second region of the second substrate do not overlap the first substrate.

A semiconductor device according to an embodiment comprises a first chip and a second chip bonded via a plurality of bonding electrodes. The first chip comprises: a first substrate; a first semiconductor element; and a first bonding electrode which is one of the plurality of bonding electrodes and is electrically connected to the first semiconductor element. The second chip comprises: a second substrate; a second semiconductor element; and a second bonding electrode which is one of the plurality of bonding electrodes and is electrically connected to the second semiconductor element. When a roughness of at least one end portion in at least one of a first direction and a second direction intersecting with the first direction, of the first substrate is assumed to be a first roughness, and a roughness of at least one end portion in at least one of the first direction and the second direction of the second substrate is assumed to be a second roughness, the first roughness is smaller than the second roughness.

In a method of manufacturing a semiconductor device according to an embodiment, a first wafer comprising a first substrate and a second wafer comprising a second substrate are bonded. Moreover, a portion provided on a dicing line, of the first substrate is removed, whereby the first substrate is divided into a plurality of portions corresponding to a plurality of dies. Moreover, the first wafer and the second wafer are divided along the dicing line, whereby the plurality of dies are formed.

Next, semiconductor devices according to embodiments will be described in detail with reference to the drawings. Note that the following embodiments are merely examples, and are not shown with the intention of limiting the present invention. Moreover, the following drawings are schematic, and, for convenience of description, some configurations, and so on, thereof will sometimes be omitted. Moreover, portions that are common to a plurality of embodiments will be assigned with the same symbols, and descriptions thereof will sometimes be omitted.

Moreover, in the present specification, when a first configuration is said to be “electrically connected” to a second configuration, the first configuration may be connected to the second configuration directly, or the first configuration may be connected to the second configuration via the likes of a wiring, a semiconductor member, or a transistor. For example, even when, in the case of three transistors having been serially connected, the second transistor is in an OFF state, the first transistor is still “electrically connected” to the third transistor.

Moreover, in the present specification, when a first configuration is said to be “connected between” a second configuration and a third configuration, it will sometimes mean that the first configuration, the second configuration, and the third configuration are serially connected, and the second configuration is connected to the third configuration via the first configuration.

Moreover, in the present specification, when a circuit, or the like, is said to “make electrically continuous” two wirings, or the like, this will sometimes mean, for example, that this circuit, or the like, includes a transistor, or the like, that this transistor, or the like, is provided in a current path between the two wirings, and that this transistor, or the like, is in an ON state.

Moreover, in the present specification, a certain direction parallel to an upper surface of a substrate will be called an X direction, a direction parallel to the upper surface of the substrate and perpendicular to the X direction will be called a Y direction, and a direction perpendicular to the upper surface of the substrate will be called a Z direction.

Moreover, in the present specification, sometimes, a direction lying along a certain plane will be called a first direction, a direction intersecting with the first direction along this certain plane will be called a second direction, and a direction intersecting this certain plane will be called a third direction. These first direction, second direction, and third direction may correspond to any of the X direction, the Y direction, and the Z direction, but need not do so.

Moreover, when expressions such as “up” or “down” are used in the present specification, the semiconductor substrate provided with a bonding pad electrode, of two semiconductor substrates included in a die may be assumed to be an upper semiconductor substrate, and the semiconductor substrate not provided with a bonding pad electrode, of the two semiconductor substrates included in the die may be assumed to be a lower semiconductor substrate, for example. Furthermore, when a configuration included in the die is referred to, an orientation of coming closer to the upper semiconductor substrate along the above-described Z direction may be called up, and an orientation of coming closer to the lower semiconductor substrate along the Z direction may be called down, for example. Moreover, when a lower surface or a lower end is referred to for a certain configuration, this may be assumed to mean a surface or end portion on a lower semiconductor substrate side of this configuration, and when an upper surface or an upper end is referred to for a certain configuration, this may be assumed to mean a surface or end portion on an upper semiconductor substrate side of this configuration. Moreover, a surface intersecting with the X direction or the Y direction may be called a side surface, and so on.

Moreover, in the present specification, when the likes of a “width”, a “length”, or a “thickness” in a certain direction is referred to for a configuration, a member, and so on, this will sometimes mean a width, a length, or a thickness, and so on, in a cross section observed by the likes of SEM (Scanning Electron Microscopy) or TEM (Transmission Electron Microscopy), and so on.

### First Embodiment

[Memory System 10]

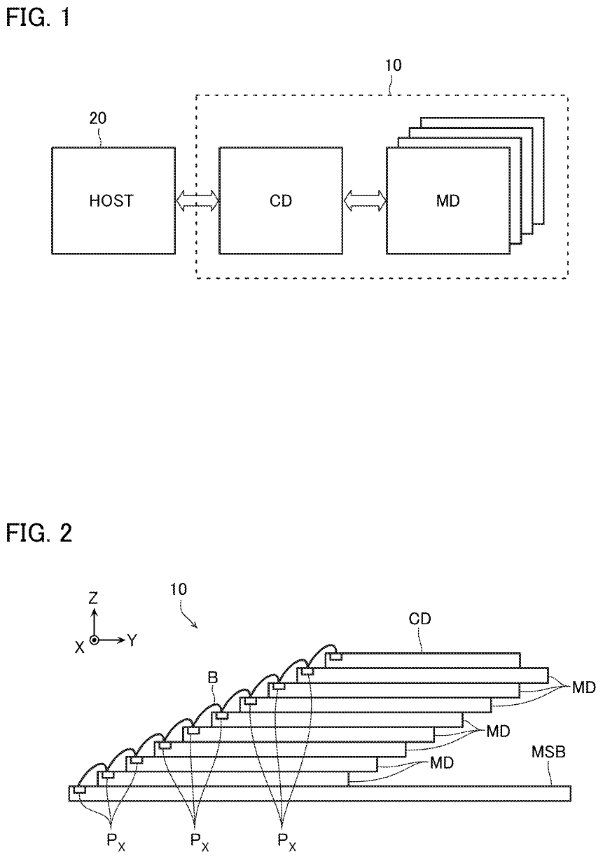

FIG. 1 is a schematic block diagram showing a configuration of a memory system 10 according to a first embodiment.

The memory system 10 performs read, write, erase, and so on, of user data, in response to a signal transmitted from a host computer 20. The memory system 10 is a memory chip, a memory card, an SSD, or another system capable of storing user data, for example. The memory system 10 comprises: a plurality of memory dies MD storing user data; and a controller die CD connected to these plurality of memory dies MD and to the host computer 20. The controller die CD comprises the likes of a processor and a RAM, for example, and performs processing, such as conversion of a logical address and a physical address, bit error detection/correction, garbage collection (compaction), and wear leveling.

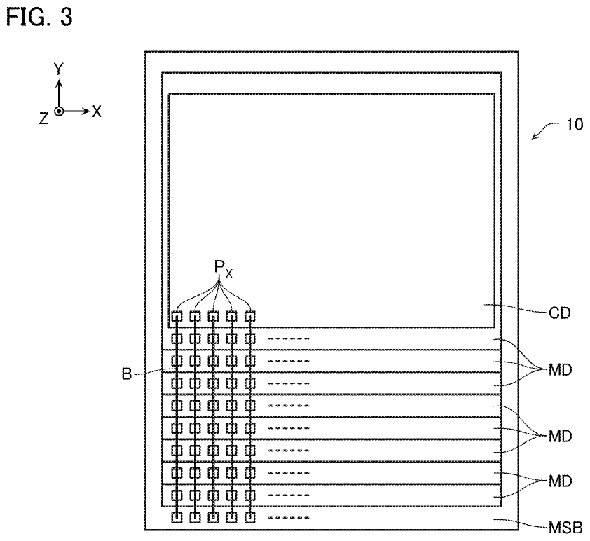

FIG. 2 is a schematic side view showing a configuration example of the memory system 10 according to the present embodiment. FIG. 3 is a schematic plan view showing same configuration example. For convenience of description, some configurations are omitted in FIGS. 2 and 3.

As shown in FIG. 2, the memory system 10 according to the present embodiment comprises: a mounting substrate MSB; a plurality of the memory dies MD stacked on the mounting substrate MSB; and the controller die CD stacked on the memory dies MD. A region of an end portion in the Y direction, of an upper surface of the mounting substrate MSB is provided with a bonding pad electrode P_{X}, and some of another region of the upper surface of the mounting substrate MSB is adhered to a lower surface of the memory die MD, via an adhesive agent, or the like. A region of an end portion in the Y direction, of an upper surface of the memory die MD is provided with the bonding pad electrode P_{X}, and another region of the upper surface of the memory die MD is adhered to a lower surface of another memory die MD or of the controller die CD, via an adhesive agent, or the like. A region of an end portion in the Y direction, of an upper surface of the controller die CD is provided with the bonding pad electrode P_{X}.

As shown in FIG. 3, the mounting substrate MSB, the plurality of memory dies MD, and the controller die CD each comprise a plurality of the bonding pad electrodes P_{X} arranged in the X direction. Pluralities of the bonding pad electrodes P_{X} provided to the mounting substrate MSB, the plurality of memory dies MD, and the controller die CD are respectively connected to each other via bonding wires B.

Note that the configuration shown in FIGS. 2 and 3 is merely an exemplification, and that a specific configuration is appropriately adjustable. For example, in the example shown in FIGS. 2 and 3, the controller die CD is stacked on the plurality of memory dies MD, and these configurations are connected by the bonding wires B. In such a configuration, the plurality of memory dies MD and the controller die CD are included in a single package. However, the controller die CD may be included in a separate package from the memory dies MD. Moreover, the plurality of memory dies MD and the controller die CD may be connected to each other via through-electrodes, or the like, not the bonding wires B.

[Structure of Memory Die MD]

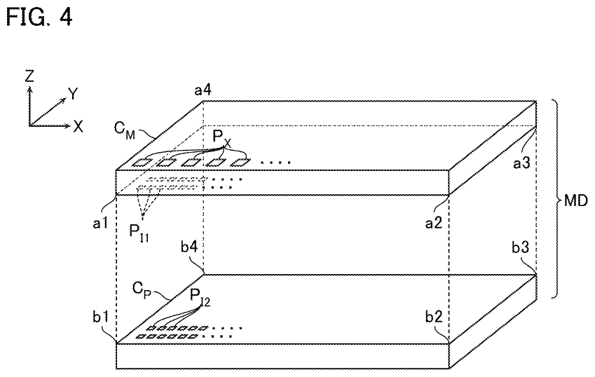

FIG. 4 is a schematic exploded perspective view showing a configuration example of a semiconductor memory device according to the present embodiment. As shown in FIG. 4, the memory die MD comprises: a chip C_{M} that includes a memory cell array MCA; and a chip C_{P} that includes a peripheral circuit.

An upper surface of the chip C_{M} is provided with a plurality of the bonding pad electrodes P_{X}. Moreover, a lower surface of the chip C_{M} is provided with a plurality of bonding electrodes P_{I1}. Moreover, an upper surface of the chip C_{P} is provided with a plurality of bonding electrodes P_{I2}. Hereafter, regarding the chip C_{M}, a surface thereof provided with the plurality of bonding electrodes P_{I1} will be called a front surface, and a surface thereof provided with the plurality of bonding pad electrodes P_{X} will be called a back surface. Moreover, regarding the chip C_{P}, a surface thereof provided with the plurality of bonding electrodes P_{I2} will be called a front surface, and a surface thereof on an opposite side to the front surface thereof will be called a back surface. In the example illustrated, the front surface of the chip C_{P} is provided above the back surface of the chip C_{P}, and the back surface of the chip C_{M} is provided above the front surface of the chip C_{M}.

The chip C_{M} and the chip C_{P} are disposed so that the front surface of the chip C_{M} faces the front surface of the chip C_{P}. The plurality of bonding electrodes P_{I1} are provided respectively correspondingly to the plurality of bonding electrodes P_{I2}, and are disposed in positions enabling them to be bonded to the plurality of bonding electrodes P_{I2}. The bonding electrodes P_{I1} and the bonding electrodes P_{I2} function as bonding electrodes for bonding and making electrically continuous the chip C_{M} and the chip C_{P}.

Note that in the example of FIG. 4, corners a1, a2, a3, a4 of the chip C_{M} respectively correspond to corners b1, b2, b3, b4 of the chip C_{P}.

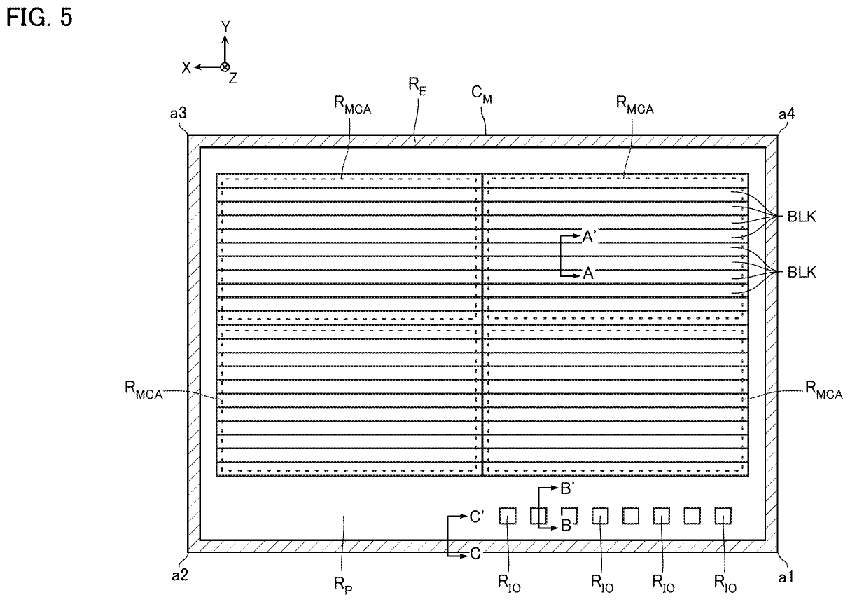

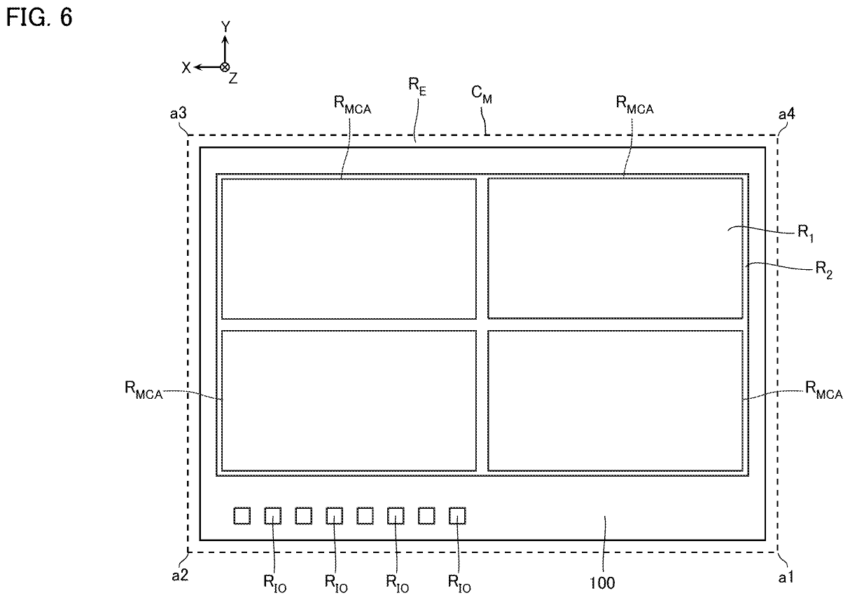

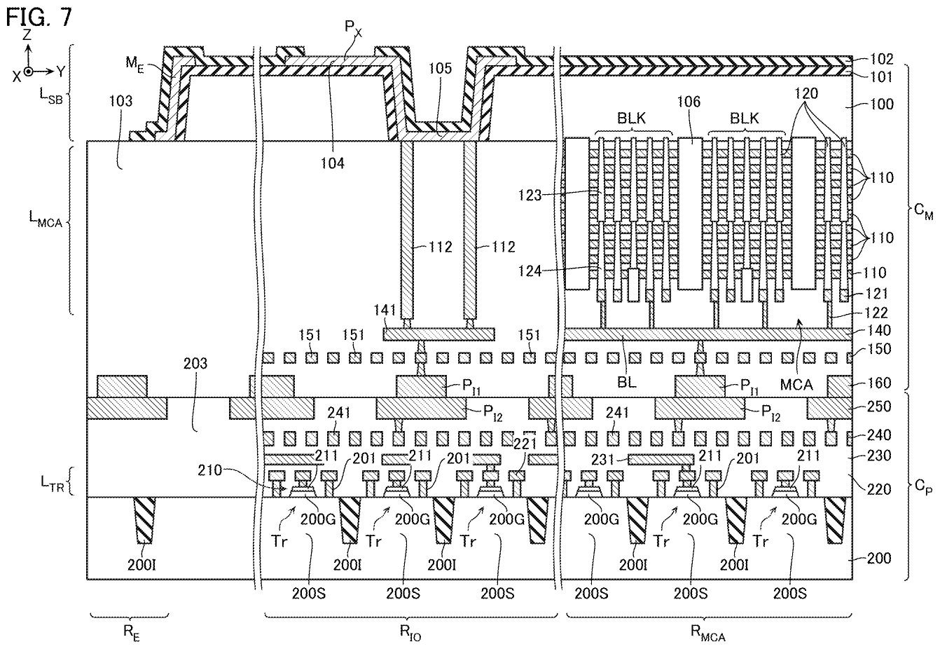

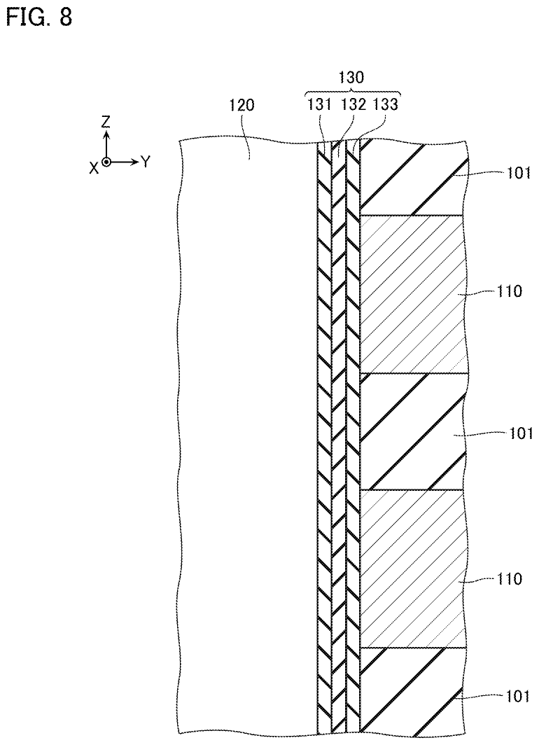

FIG. 5 is a schematic bottom view showing a configuration example of the chip C_{M}. FIG. 6 is a schematic bottom view showing a configuration of a semiconductor substrate 100 included in the chip C_{M}. FIG. 7 is a schematic cross-sectional view showing a configuration of the memory die MD. Note that FIG. 7 includes a cross section in which the configuration shown in FIG. 5 has been cut along the line A-A′ and viewed in a direction of the arrows. Moreover, FIG. 7 includes a cross section in which the configuration shown in FIG. 5 has been cut along the line B-B′ and viewed in a direction of the arrows. Moreover, FIG. 7 includes a cross section in which the configuration shown in FIG. 5 has been cut along the line C-C′ and viewed in a direction of the arrows. FIG. 8 is a schematic enlarged view of a configuration of part of FIG. 7.

[Structure of Chip C_{M}]

As shown in FIG. 5, for example, the chip C_{M} comprises four memory cell array regions R_{MCA} arranged in the X direction and the Y direction. Moreover, the chip C_{M} comprises a peripheral region R_{P} which is provided on one side in the Y direction (for example, a lower side in FIG. 5) of these four memory cell array regions R_{MCA}. The peripheral region R_{P} comprises a plurality of input/output circuit regions R_{IO} arranged in the X direction. Moreover, the four sides of the chip C_{M} are provided with an edge region R_{E}. That is, the edge region R_{E} comprises: two regions which are provided in both end portions in the X direction and extend in the Y direction; and two regions which are provided in both end portions in the Y direction and extend in the X direction.

As shown in FIG. 7, for example, the chip C_{M} comprises: a substrate layer L_{SB}; a memory cell array layer L_{MCA} provided below the substrate layer L_{SB}; and a plurality of wiring layers 140, 150, 160 provided below the memory cell array layer L_{MCA}. Moreover, an insulating layer 103 of the likes of silicon oxide (SiO₂) is embedded between configurations in the memory cell array layer L_{MCA} and the wiring layers 140, 150, 160.

[Structure of Substrate Layer L_{SB} of Chip C_{M}]

As shown in FIG. 7, for example, the substrate layer L_{SB} comprises: the semiconductor substrate 100; an insulating layer 101 provided on an upper surface of the semiconductor substrate 100; and an insulating layer 102 provided on an upper surface of the insulating layer 101. Moreover, the input/output circuit region R_{IO} is provided with the bonding pad electrode P_{X} which is provided between the insulating layer 101 and the insulating layer 102.

The semiconductor substrate 100 is a semiconductor substrate of the likes of silicon (Si) implanted with an N type impurity such as phosphorus (P) or a P type impurity such as boron (B), for example.

As shown in FIG. 6, for example, the semiconductor substrate 100 is provided with: four regions R₁ corresponding to the four memory cell array regions R_{MCA}; and a region R₂ surrounding these four regions R₁. The four regions R₁ are electrically independent from each other, for example.

These four regions R₁ may be configured electrically independently from each other by a well structure, for example. In the case where, for example, the semiconductor substrate 100 is a P type semiconductor substrate including a P type impurity, the region R₂ may be an N type well including an N type impurity. Moreover, the region R₁ may be a P type well including a P type impurity.

Moreover, these four regions R₁ may be configured electrically independently from each other by an insulating layer, for example. For example, the region R₂ may have STI (Shallow Trench Isolation) including an insulating layer of the likes of silicon oxide (SiO₂).

Moreover, these four regions R₁ may be physically divided from each other, for example. For example, the semiconductor substrate 100 may comprise: four portions corresponding to the four region R₁; and one portion corresponding to a region other than the four regions R₁. Moreover, the region R₂ may be a trench dividing these five portions.

Moreover, the semiconductor substrate 100 is provided with a plurality of contact holes, correspondingly to the plurality of input/output circuit regions R_{IO}. As shown in FIG. 7, for example, insides of these plurality of contact holes are provided with part of the bonding pad electrode P_{X}.

Moreover, the semiconductor substrate 100 is not provided in the edge region R_{E}. Hence, in the case of the memory die MD being viewed from the Z direction, as shown in FIG. 6, for example, in the edge region, the insulating layer 103 and an insulating layer 203 and semiconductor substrate 200 in the chip C_{P} do not overlap the semiconductor substrate 100 (refer to FIG. 7).

Note that a roughness of side surfaces in the X direction and the Y direction of the semiconductor substrate 100 is smaller than a roughness of side surfaces in the X direction and the Y direction of the semiconductor substrate 200 in the chip C_{P}.

Note that the semiconductor substrate 100 undergoes layer-thinning from a back surface side (an upper side in FIG. 7) by a later-mentioned method of manufacturing. Hence, a thickness in the Z direction of the semiconductor substrate 100 is smaller than a thickness in the Z direction of the semiconductor substrate 200. As a result, a thickness in the Z direction of the chip C_{M} is smaller than a thickness in the Z direction of the chip C_{P}.

The insulating layer 101 (FIG. 7) is an insulating layer configured from an insulating material of the likes of silicon oxide (SiO₂), for example. As shown in FIG. 7, for example, the insulating layer 101 covers the upper surface and side surfaces in the X direction and Y direction, of the semiconductor substrate 100. Note that the insulating layer 101 may cover an upper surface of the insulating layer 103 in the edge region R_{E}, but need not do so.

The insulating layer 102 is a passivation layer configured from an insulating material of the likes of a polyimide, for example. As shown in FIG. 7, for example, the insulating layer 102 covers the upper surface and side surfaces in the X direction and Y direction, of the semiconductor substrate 100, via the insulating layer 101, and so on. Note that the insulating layer 102 may cover the upper surface of the insulating layer 103 in the edge region R_{E}, but need not do so.

The bonding pad electrode P_{X} includes a conductive material such as aluminum (Al), for example. As shown in FIG. 7, for example, the bonding pad electrode P_{X} comprises: an external connection region 104 provided on the upper surface of the semiconductor substrate 100 via the insulating layer 101; and an internal connection region 105 provided on an inner peripheral surface and bottom surface of the contact hole.

The external connection region 104 is a region connected to the bonding wire B (FIGS. 2 and 3). At least part of a portion corresponding to the external connection region 104, of the insulating layer 102 is provided with an opening. The external connection region 104 is exposed to a region on an outer side of the memory die MD via this opening.

The internal connection region 105 is a region connected to a contact 112 included in the memory cell array layer L_{MCA}. The internal connection region 105 covers the upper surface of the insulating layer 103 of the likes of silicon oxide (SiO₂) included in the memory cell array layer L_{MCA}, at the bottom surface of the contact hole provided in the semiconductor substrate 100.

Note that as shown in FIG. 7, the side surfaces in the X direction and the Y direction of the semiconductor substrate 100 are provided with a metal layer M_{E}, via the insulating layer 101. The metal layer M_{E} comprises the same material and has the same degree of film thickness as the bonding pad electrode P_{X}. The metal layer M_{E} may cover the side surfaces in the X direction and the Y direction of the semiconductor substrate 100 over an entire periphery thereof, or may cover only part of the side surfaces in the X direction and the Y direction of the semiconductor substrate 100.

[Structure of Memory Cell Array Layer L_{MCA} of Chip C_{M}]

As shown in FIG. 7, for example, the memory cell array region R_{MCA} of the memory cell array layer L_{MCA} is provided with the memory cell array MCA. The memory cell array MCA comprises: a plurality of memory blocks BLK arranged in the Y direction; and an inter-block insulating layer 106 of the likes of silicon oxide (SiO₂) provided between each of these plurality of memory blocks BLK.

The memory block BLK comprises: a plurality of conductive layers 110 arranged in the Z direction; a plurality of semiconductor layers 120 extending in the Z direction; and a plurality of gate insulating films 130 (FIG. 8) respectively provided between the plurality of conductive layers 110 and the plurality of semiconductor layers 120.

The conductive layer 110 is a substantially plate-like conductive layer extending in the X direction. The conductive layer 110 may include a stacked film of a barrier conductive film of the likes of titanium nitride (TiN) and a metal film of the likes of tungsten (W), or the like. Moreover, the conductive layer 110 may include the likes of polycrystalline silicon including an impurity such as phosphorus (P) or boron (B), for example. An insulating layer of the likes of silicon oxide (SiO₂) is provided between the plurality of conductive layers 110 arranged in the Z direction. These plurality of conductive layers 110 function for example as word lines and as gate electrodes of a plurality of memory cells connected to these word lines, and so on.

The semiconductor layer 120 functions for example as channel regions of the plurality of memory cells, and so on.

The semiconductor layer 120 is a semiconductor layer of the likes of polycrystalline silicon (Si), for example. The semiconductor layer 120 has a substantially circular columnar shape, for example. Moreover, an outer peripheral surface of the semiconductor layer 120 is surrounded by respective ones of the conductive layers 110, and faces the conductive layers 110.

A lower end portion of the semiconductor layer 120 is provided with an unillustrated impurity region including an N type impurity such as phosphorus (P). This impurity region is connected to a bit line BL via a contact 121 and a contact 122.

An upper end portion of the semiconductor layer 120 is provided with an unillustrated impurity region including an N type impurity such as phosphorus (P) or a P type impurity such as boron (B). This impurity region is connected to the semiconductor substrate 100.

Note that the semiconductor layer 120 exemplified in FIG. 7 comprises: a portion 123 facing approximately that half of the conductive layers 110 provided on an upper side; and a portion 124 facing approximately that half of the conductive layers 110 provided on a lower side. Widths in the X direction and the Y direction of an upper end portion of the portion 123 are smaller than widths in the X direction and the Y direction of a lower end portion of the portion 123. Moreover, widths in the X direction and the Y direction of an upper end portion of the portion 124 are smaller than widths in the X direction and the Y direction of a lower end portion of the portion 124. Moreover, widths in the X direction and the Y direction of the upper end portion of the portion 124 are smaller than widths in the X direction and the Y direction of the lower end portion of the portion 123. However, the semiconductor layer 120 need not comprise such a shape.

The gate insulating film 130 (FIG. 8) has a substantially cylindrical shape covering the outer peripheral surface of the semiconductor layer 120. The gate insulating film 130 comprises a tunnel insulating film 131, a charge accumulating film 132, and a block insulating film 133 that are stacked between the semiconductor layer 120 and the conductive layers 110. The tunnel insulating film 131 and the block insulating film 133 are insulating films of the likes of silicon oxide (SiO₂), for example. The charge accumulating film 132 is a film capable of accumulating a charge, of the likes of silicon nitride (Si₃N₄), for example. The tunnel insulating film 131, the charge accumulating film 132, and the block insulating film 133 have substantially cylindrical shapes, and extend in the Z direction along the outer peripheral surface of the semiconductor layer 120.

Note that FIG. 8 shows an example where the gate insulating film 130 comprises the charge accumulating film 132 of the likes of silicon nitride. However, the gate insulating film 130 may comprise a floating gate of the likes of polycrystalline silicon including an N type or P type impurity, for example.

Moreover, as shown in FIG. 7, for example, the input/output circuit region R_{IO} of the memory cell array layer L_{MCA} comprises a plurality of the contacts 112 extending in the Z direction penetrating the insulating layer 103.

The contact 112 includes for example a stacked film of a barrier conductive film of the likes of titanium nitride (TiN) and a metal film of the likes of tungsten (W), or the like. The contact 112 has a substantially cylindrical shape, for example. Upper ends of these plurality of contacts 112 are respectively connected to lower surfaces of the internal connection regions 105 of the bonding pad electrodes P_{X}. Moreover, the plurality of contacts 112 are each connected at their lower ends to a wiring 141.

[Structure of Wiring Layers 140, 150, 160 of Chip C_{M}]

A plurality of wirings included in the wiring layers 140, 150, 160 are electrically connected to at least one of configurations in the memory cell array layer L_{MCA} and configurations in the chip C_{P}, for example.

The wiring layer 140 includes a plurality of the wirings 141. These plurality of wirings 141 may include for example a stacked film of a barrier conductive film of the likes of titanium nitride (TiN) and a metal film of the likes of copper (Cu), or the like. Note that some of the plurality of wirings 141 function as the bit lines BL. The bit lines BL are arranged in the X direction and extend in the Y direction, for example. Moreover, these plurality of bit lines BL are respectively connected to the plurality of semiconductor layers 120.

The wiring layer 150 includes a plurality of wirings 151. These plurality of wirings 151 may include for example a stacked film of a barrier conductive film of the likes of titanium nitride (TiN) and a metal film of the likes of copper (Cu), or the like.

The wiring layer 160 includes a plurality of the bonding electrodes P_{I1}. These plurality of bonding electrodes P_{I1} may include for example a stacked film of a barrier conductive film of the likes of titanium nitride (TiN) and a metal film of the likes of copper (Cu), or the like.

[Structure of Chip C_{P}]

The chip C_{P} comprises, for example: the semiconductor substrate 200; a transistor layer L_{TR} provided above the semiconductor substrate 200; and a plurality of wiring layers 220, 230, 240, 250 provided above the transistor layer L_{TR}. Moreover, the insulating layer 203 of the likes of silicon oxide (SiO₂) is embedded between configurations in the transistor layer L_{TR} and the wiring layers 220, 230, 240, 250. Note that it is possible too to employ as a material of the insulating layer 203 a material having a lower dielectric constant than a material of the insulating layer 103.

[Structure of Semiconductor Substrate 200 of Chip C_{P}]

The semiconductor substrate 200 is a semiconductor substrate configured from P type silicon (Si) including a P type impurity such as boron (B), for example. A surface of the semiconductor substrate 200 is provided with a semiconductor substrate region 200S and an insulating region 200I.

The semiconductor substrate 200 is provided over all of the regions in the memory die MD including the edge region R_{E}.

[Structure of Transistor Layer L_{TR} of Chip C_{P}]

The semiconductor substrate 200 has its upper surface provided with an electrode layer 210 via an insulating layer 200G. The electrode layer 210 includes a plurality of electrodes 211 that face the surface of the semiconductor substrate 200. Moreover, each of regions of the semiconductor substrate 200 and the plurality of electrodes 211 included in the electrode layer 210 are respectively connected to contacts 201.

The semiconductor substrate region 200S of the semiconductor substrate 200 functions as channel regions of a plurality of transistors Tr configuring the peripheral circuit, and so on.

The plurality of electrodes 211 included in the electrode layer 210 respectively function as gate electrodes of the plurality of transistors Tr configuring the peripheral circuit, and so on. The electrode 211 comprises: a semiconductor layer of the likes of polycrystalline silicon (Si) including an N type impurity such as phosphorus (P) or a P type impurity such as boron (B), for example; and a metal layer of the likes of tungsten (W) provided on an upper surface of this semiconductor layer.

The contact 201 extends in the Z direction and has its lower end connected to an upper surface of the semiconductor substrate 200 or electrode 211. The contact 201 may include for example a stacked film of a barrier conductive film of the likes of titanium nitride (TiN) and a metal film of the likes of tungsten (W), or the like.

Note that the plurality of transistors Tr provided in the semiconductor substrate 200 each configure part of the peripheral circuit.

[Structure of Wiring Layers 220, 230, 240, 250 of Chip C_{P}]

A plurality of wirings included in the wiring layers 220, 230, 240, 250 are electrically connected to at least one of configurations in the transistor layer L_{TR} and configurations in the chip C_{M}, for example.

The wiring layer 220 includes a plurality of wirings 221. These plurality of wirings 221 may include for example a stacked film of a barrier conductive film of the likes of titanium nitride (TiN) and a metal film of the likes of copper (Cu), or the like.

The wiring layer 230 includes a plurality of wirings 231. These plurality of wirings 231 may include for example a stacked film of a barrier conductive film of the likes of titanium nitride (TiN) and a metal film of the likes of copper (Cu), or the like.

The wiring layer 240 includes a plurality of wirings 241. These plurality of wirings 241 may include for example a stacked film of a barrier conductive film of the likes of titanium nitride (TiN) and a metal film of the likes of copper (Cu), or the like.

The wiring layer 250 includes a plurality of the bonding electrodes P_{I2}. These plurality of bonding electrodes P_{I2} may include for example a stacked film of a barrier conductive film of the likes of titanium nitride (TiN) and a metal film of the likes of copper (Cu), or the like.

[Method of Manufacturing Memory Die MD]

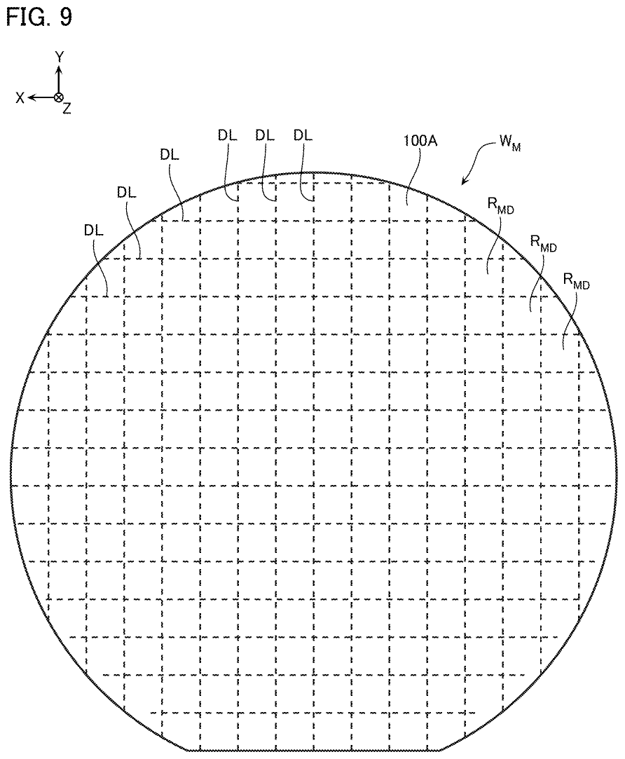

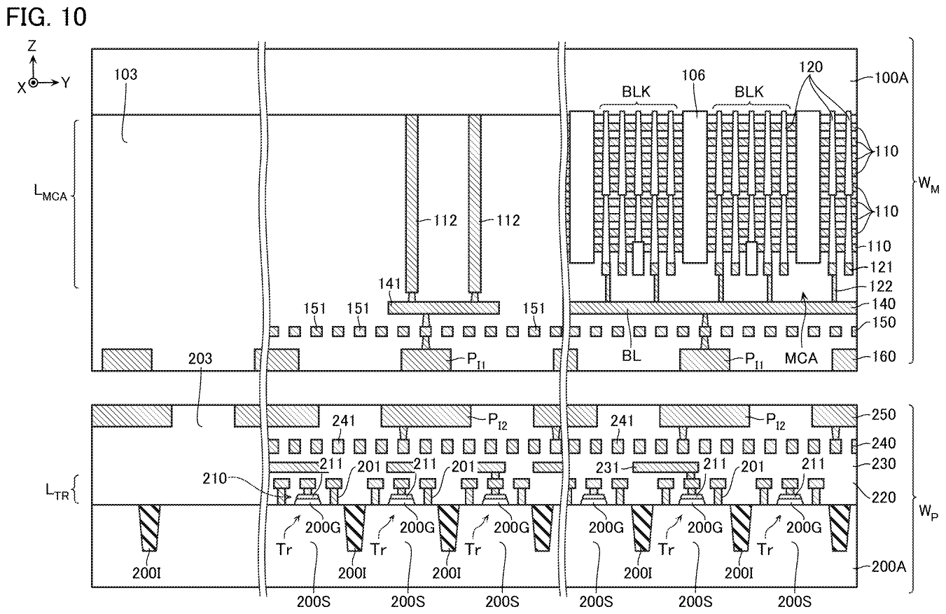

Next, a method of manufacturing the memory die MD will be described with reference to FIGS. 9 to 21. FIG. 9 is a schematic bottom view for explaining same method of manufacturing. FIGS. 10 to 12, and 14 to 21 are schematic cross-sectional views for explaining same method of manufacturing. Note that FIGS. 10 to 12, and 14 to 19 show portions corresponding to FIG. 7. FIG. 13 is a schematic plan view for explaining same method of manufacturing.

FIG. 9 exemplifies a wafer W_{M} employed in manufacturing of the chip C_{M}. A semiconductor substrate 100A of the wafer W_{M} is provided with a plurality of dicing lines DL extending in the X direction or the Y direction. Moreover, each of regions partitioned by these plurality of dicing lines DL represents a memory die region R_{MD}.

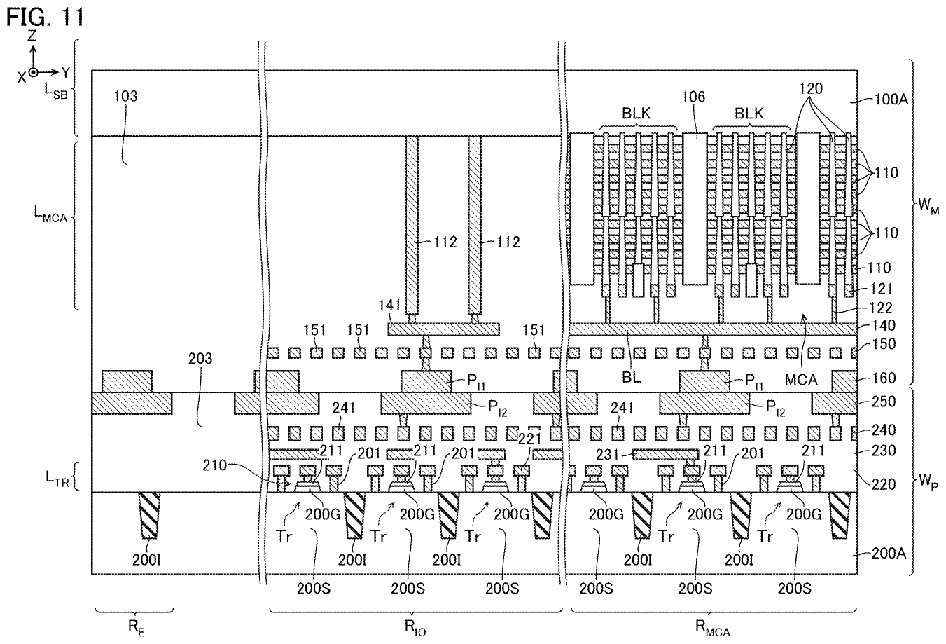

In this method of manufacturing, as shown in FIGS. 10 and 11, for example, the wafer W_{M} employed in manufacturing of the chip C_{M} and a wafer W_{P} employed in manufacturing of the chip C_{P} are bonded. In this bonding step, for example, the wafer W_{M} is closely adhered to the wafer W_{P} by the wafer W_{M} being pressed against the wafer W_{P}, and heat treatment or the like is performed. As a result, the wafer W_{M} is bonded to the wafer W_{P} via the bonding electrodes P_{I1} and the bonding electrodes P_{I2}.

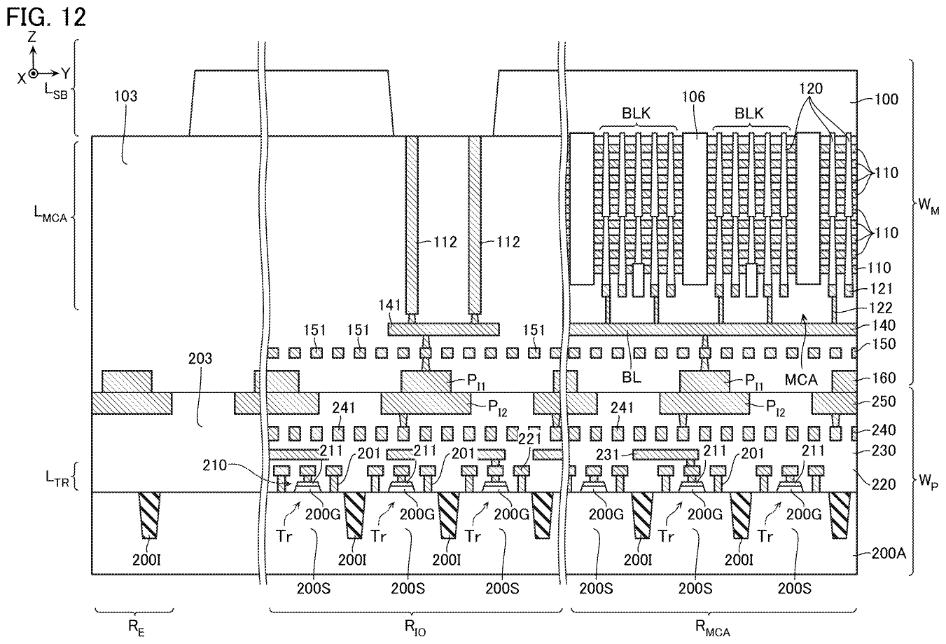

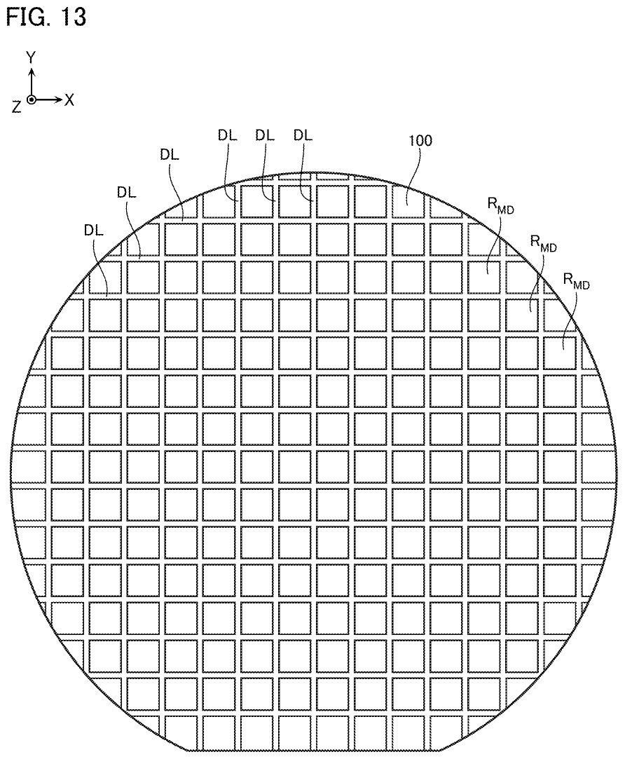

Next, as shown in FIG. 12, for example, the semiconductor substrate 100A undergoes layer-thinning by back surface polishing, and then part of the semiconductor substrate 100A is removed, whereby the contact hole corresponding to the bonding pad electrode P_{X} is formed. Moreover, as shown in FIGS. 12 and 13, for example, part of the semiconductor substrate 100A is removed on the dicing line DL and in the edge region R_{E}. As a result, the insulating layer 103 is exposed on the bottom surface of the contact hole, on the dicing line DL, and in the edge region R_{E}. Moreover, the semiconductor substrate 100 is formed. This step is performed by a method such as RIE (Reactive Ion Etching), for example. Note that due to this step, a thickness in the Z direction of the semiconductor substrate 100A becomes smaller than a thickness in the Z direction of a semiconductor substrate 200A.

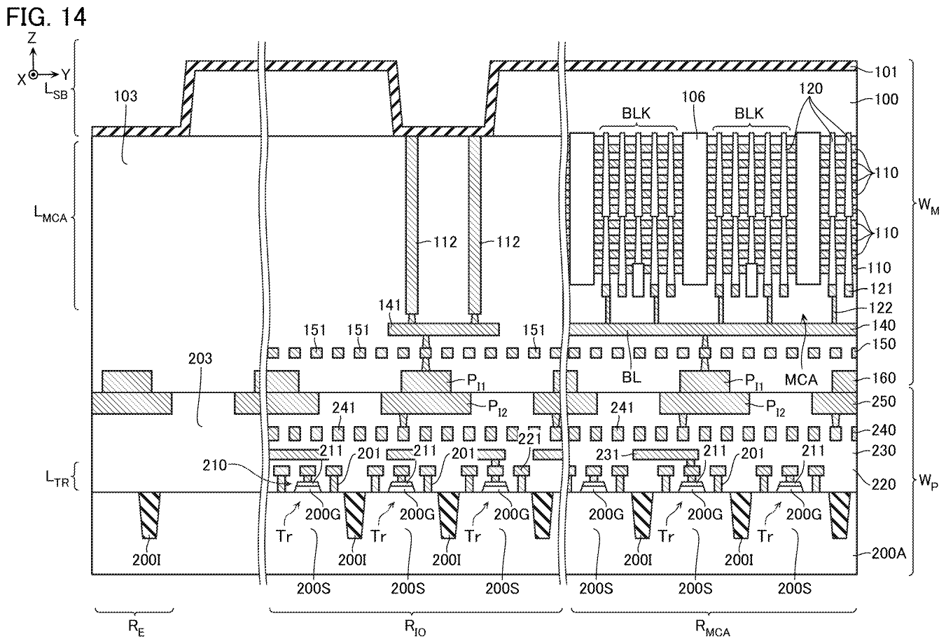

Next, as shown in FIG. 14, for example, the insulating layer 101 is formed on an upper surface of the structure shown in FIG. 12. This step is performed by a method such as CVD (Chemical Vapor Deposition), for example.

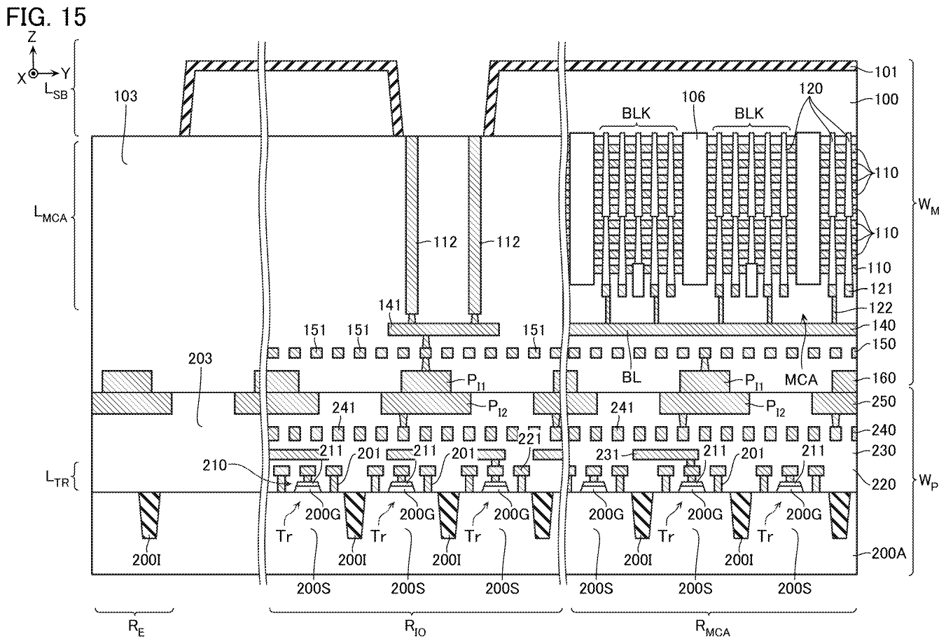

Next, as shown in FIG. 15, for example, the insulating layer 101 is removed on the bottom surface of the contact hole, on the dicing line DL, and in the edge region R_{E}. As a result, the insulating layer 103 is exposed on the bottom surface of the contact hole, on the dicing line DL, and in the edge region R_{E}. This step is performed by a method such as RIE, for example.

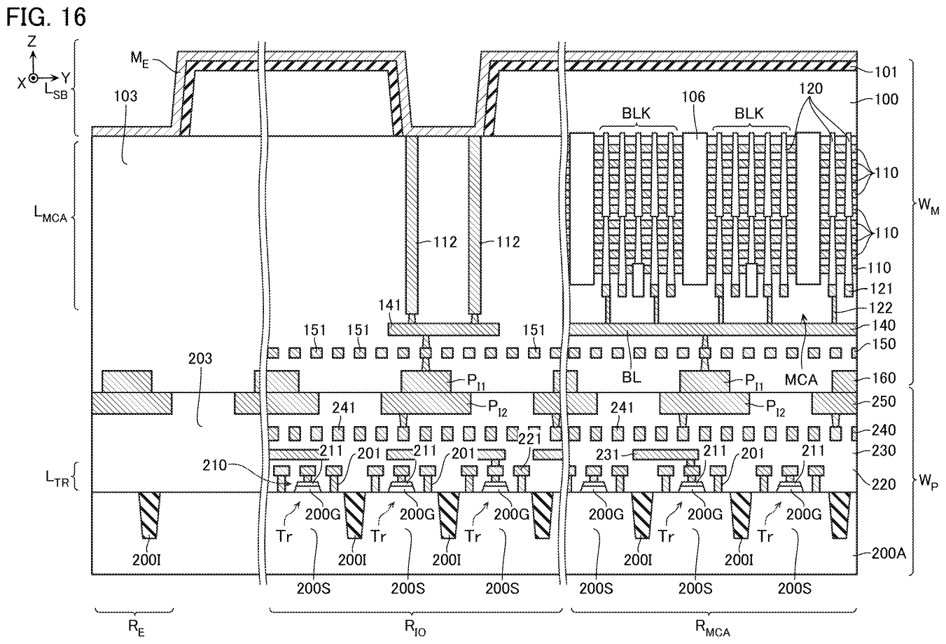

Next, as shown in FIG. 16, for example, the metal layer M_{E} is formed on the upper surface of the insulating layer 101, on the side surfaces in the X direction and the Y direction of the insulating layer 101 (including on the inner peripheral surface of the contact hole), and on the upper surface of the insulating layer 103. This step is performed by a method such as CVD, for example.

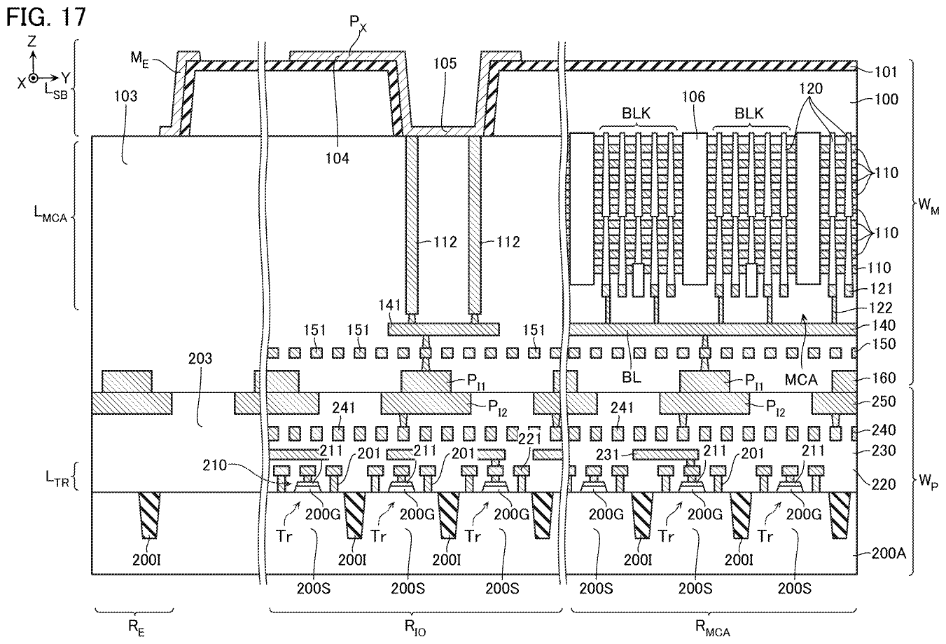

Next, as shown in FIG. 17, for example, part of the metal layer M_{E} is removed, whereby the bonding pad electrode P_{X} is formed. This step is performed by a method such as RIE, for example. Note that in this step, as illustrated, the metal layer M_{E} may be left unremoved on the side surfaces in the X direction and the Y direction of the insulating layer 101.

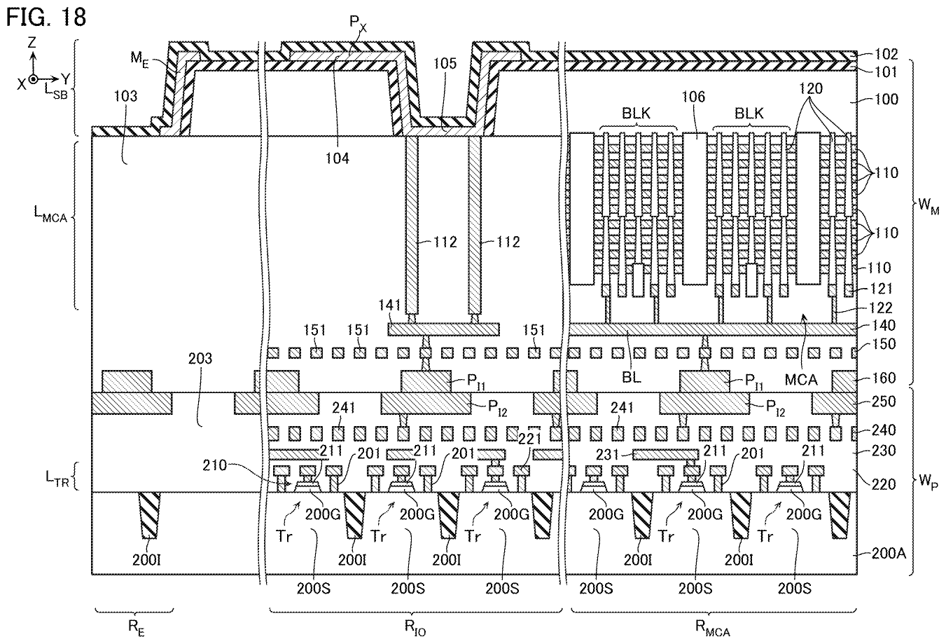

Next, as shown in FIG. 18, for example, the insulating layer 102 is formed on the upper surface of the insulating layer 101, on the upper surface of the metal layer M_{E}, on the side surfaces in the X direction and the Y direction of the metal layer M_{E} (including on the inner peripheral surface inside the contact hole), and on the upper surface of the insulating layer 103. This step is performed by a method such as CVD, for example.

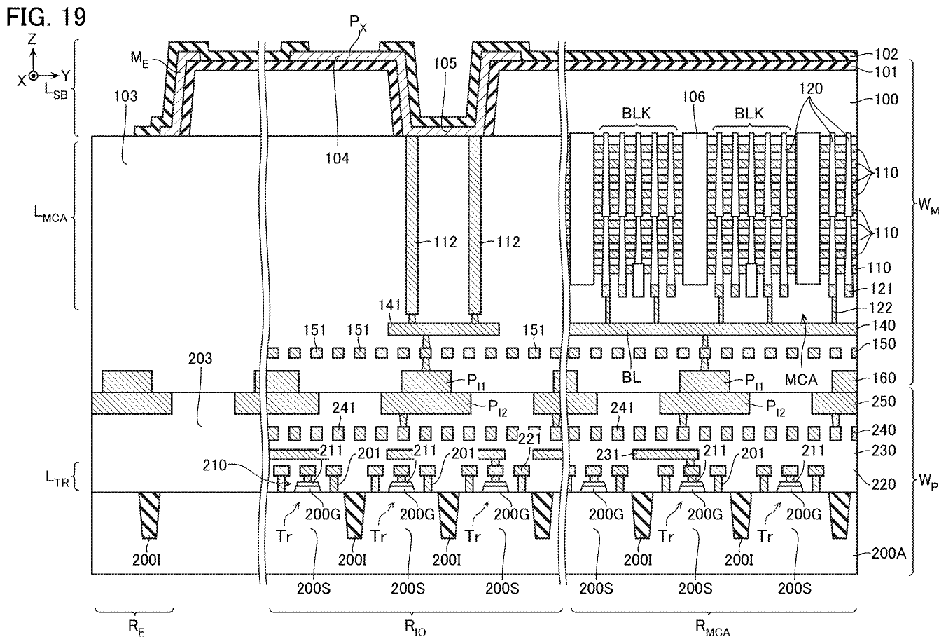

Next, as shown in FIG. 19, for example, part of the insulating layer 102 is removed, whereby part of the external connection region 104 of the bonding pad electrode P_{X} is exposed. This step is performed by a method such as RIE, for example. Note that in this step, the insulating layer 102 may be removed in the edge region R_{E} as illustrated, but need not be so removed.

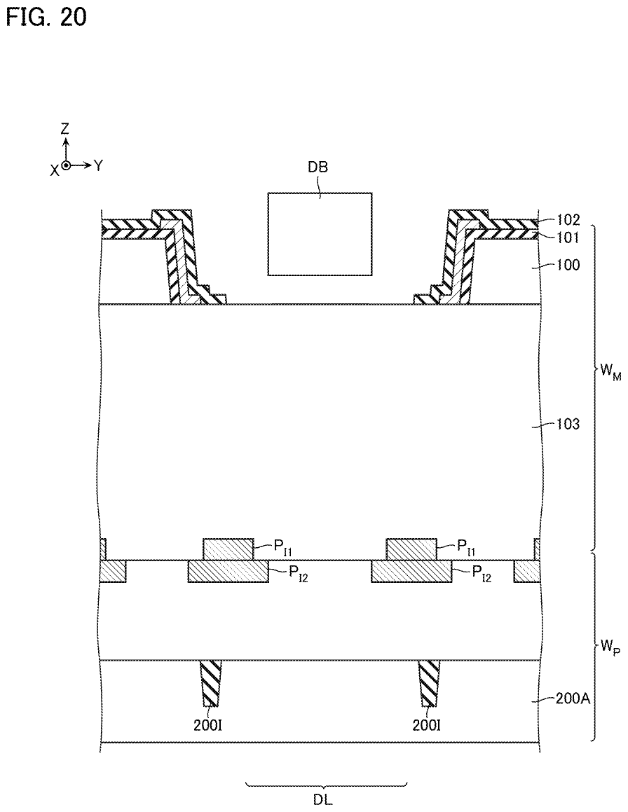

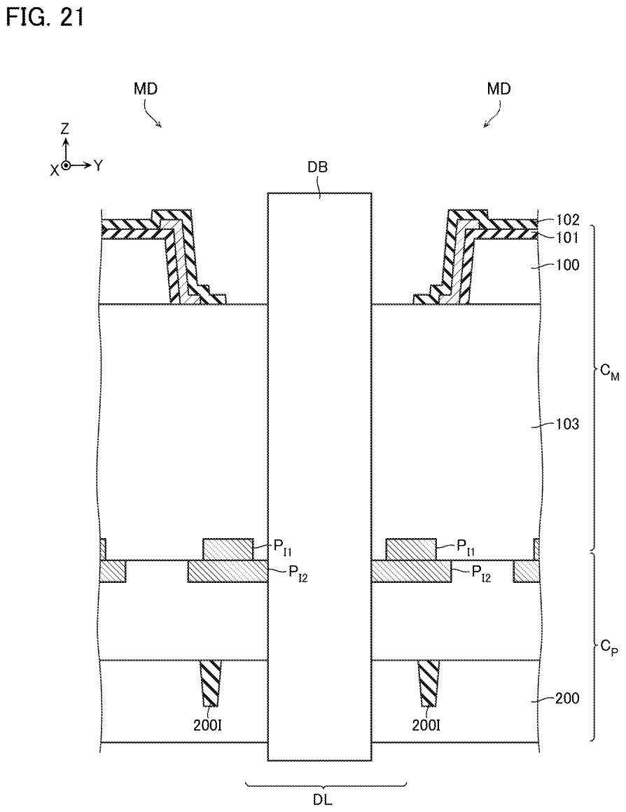

Next, as shown in FIGS. 20 and 21, for example, the wafers W_{M}, W_{P} are cut along the dicing line DL. As a result, the configurations provided in each of the memory die regions R_{MD} each become the memory die MD. Note that FIGS. 20 and 21 exemplify a situation of the wafers W_{M}, W_{P} being cut by a dicing blade DB.

Note that, for example, when the step described with reference to FIGS. 12 and 13 has been performed by a method such as RIE, a roughness on the inner peripheral surface of the contact hole and on the side surfaces in the X direction and the Y direction of the semiconductor substrate 100 becomes comparatively small. On the other hand, when the step described with reference to FIGS. 20 and 21 has been performed using the likes of the dicing blade DB, a roughness on the side surfaces in the X direction and the Y direction of the semiconductor substrate 200 becomes comparatively large. In such a case, the roughness on the side surfaces in the X direction and the Y direction of the semiconductor substrate 100 sometimes becomes smaller than the roughness on the side surfaces in the X direction and the Y direction of the semiconductor substrate 200.

### Comparative Example

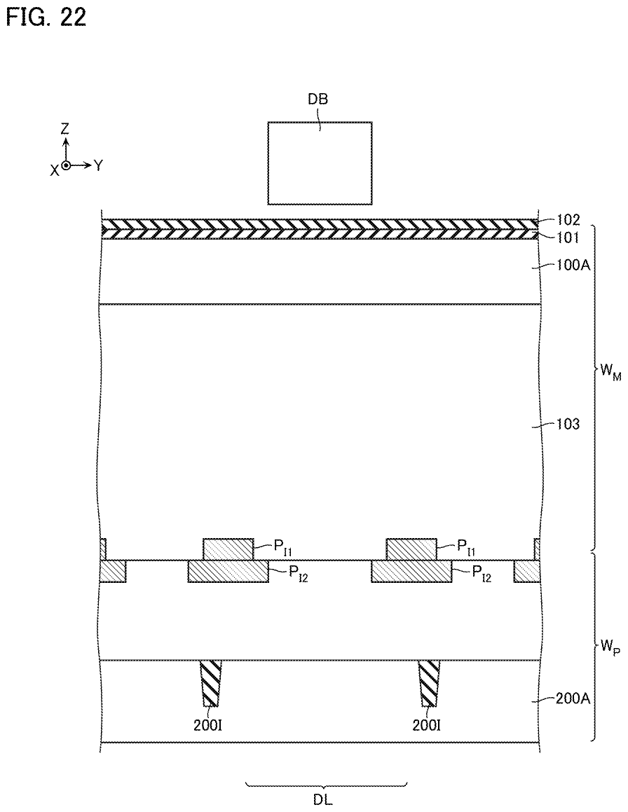

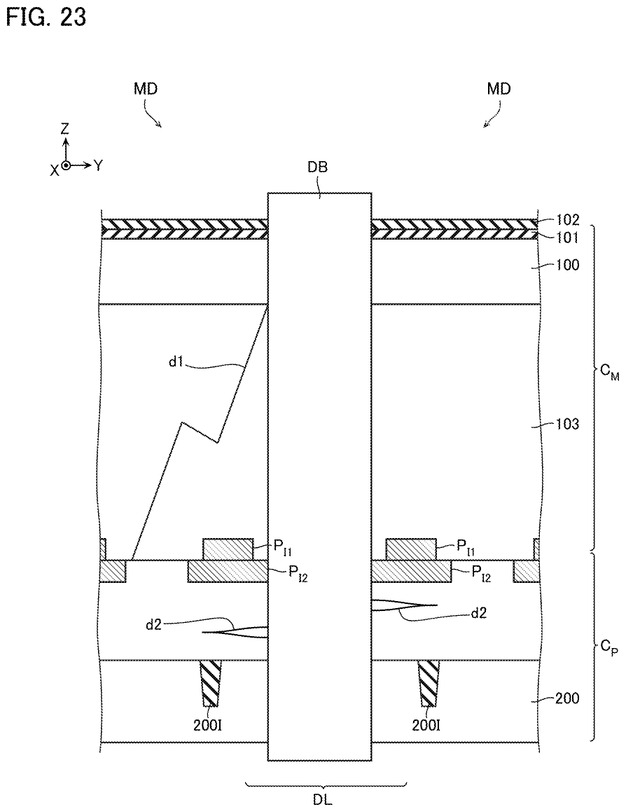

Next, a method of manufacturing a semiconductor memory device according to a comparative example will be described with reference to FIGS. 22 and 23. FIGS. 22 and 23 are schematic cross-sectional views for explaining same method of manufacturing.

In the method of manufacturing a semiconductor memory device according to the first embodiment, as described with reference to FIGS. 12 and 13, in the step of forming the contact hole corresponding to the bonding pad electrode P_{X}, part of the semiconductor substrate 100 was removed along the dicing line DL. On the other hand, in the method of manufacturing according to the comparative example, removal of part of the semiconductor substrate 100 along the dicing line DL is not performed in this step.

Moreover, as shown in FIGS. 22 and 23, when the wafers W_{M}, W_{P} are cut along the dicing line DL, the semiconductor substrates 100A, 200A are left on the dicing line DL.

In such a method, configurations between the semiconductor substrates 100A, 200A are readily subjected to stress by the dicing blade DB, and, sometimes, as exemplified in FIG. 23, a crack d1 ends up occurring in configurations in the wafers W_{M}, W_{P}, or a film-peeling d2 ends up occurring in configurations in the wafers W_{M}, W_{P}.

[Advantages]

In the method of manufacturing a semiconductor memory device according to the first embodiment, as described with reference to FIGS. 12 and 13, in the step of forming the contact hole corresponding to the bonding pad electrode P_{X}, part of the semiconductor substrate 100A is removed along the dicing line DL. Hence, as shown in FIGS. 20 and 21, when the wafers W_{M}, W_{P} are cut along the dicing line DL, the semiconductor substrate 100A is not left on the dicing line DL. Hence, it is possible for occurrence of a crack or film-peeling, and so on, to be more suitably suppressed compared to in the method of manufacturing according to the comparative example.

Moreover, in the method of manufacturing a semiconductor memory device according to the first embodiment, in the step described with reference to FIGS. 12 and 13, forming of the contact hole corresponding to the bonding pad electrode P_{X} and removal of part of the semiconductor substrate 100A lying along the dicing line DL are performed in one step. As a result, an increase in the number of manufacturing steps can be suppressed.

### Second Embodiment

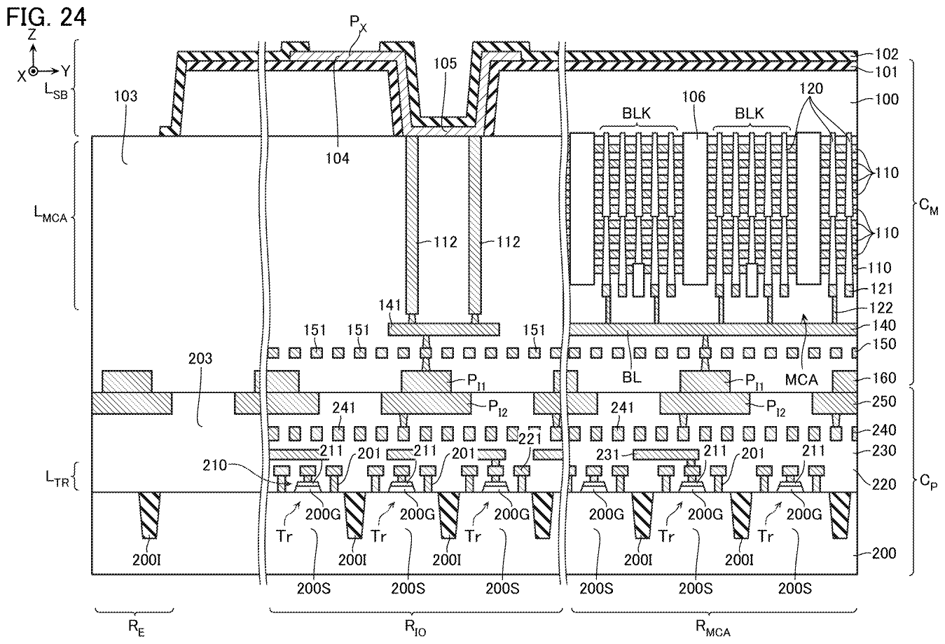

Next, a configuration of a semiconductor memory device according to a second embodiment will be described with reference to FIG. 24. FIG. 24 is a schematic cross-sectional view showing a configuration of part of the semiconductor memory device according to the second embodiment.

The semiconductor memory device according to the second embodiment is basically configured similarly to the semiconductor memory device according to the first embodiment. However, as described with reference to FIG. 7, in the first embodiment, the side surfaces in the X direction and the Y direction of the semiconductor substrate 100 were covered by the insulating layer 101 and the metal layer M_{E}. On the other hand, as shown in FIG. 24, in the second embodiment, the side surfaces in the X direction and the Y direction of the semiconductor substrate 100 are not covered by the insulating layer 101 and the metal layer M_{E}.

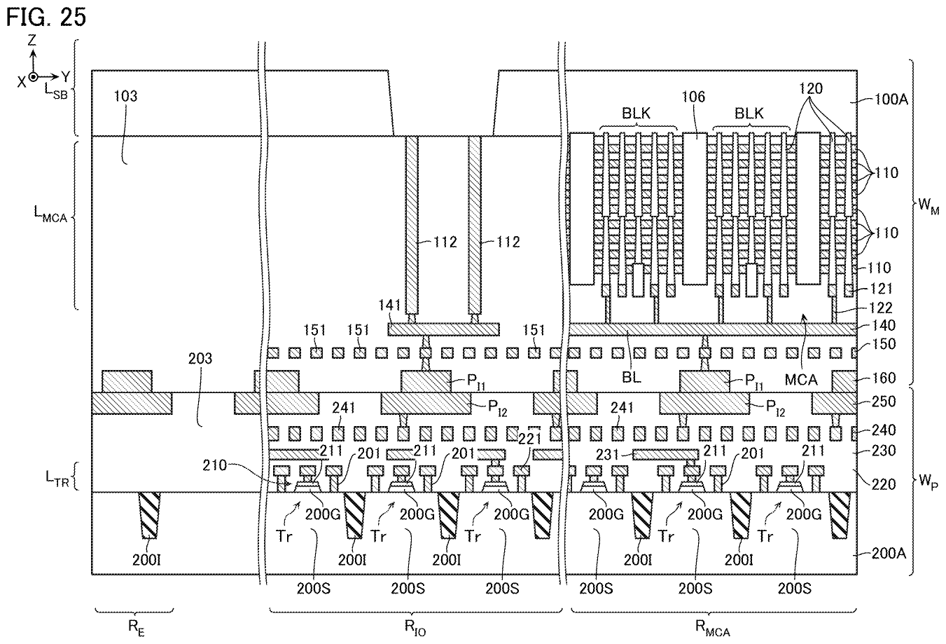

Next, a method of manufacturing a semiconductor memory device according to the second embodiment will be described with reference to FIGS. 25 to 29. FIGS. 25 to 29 are schematic cross-sectional views for explaining same method of manufacturing.

In the method of manufacturing a semiconductor memory device according to the second embodiment, steps up to the step described with reference to FIG. 11, of the method of manufacturing a semiconductor memory device according to the first embodiment are executed.

Next, as shown in FIG. 25, for example, part of the semiconductor substrate 100A is removed, whereby the contact hole corresponding to the bonding pad electrode P_{X} is formed. As a result, the insulating layer 103 is exposed on the bottom surface of the contact hole. This step is performed by a method such as RIE, for example.

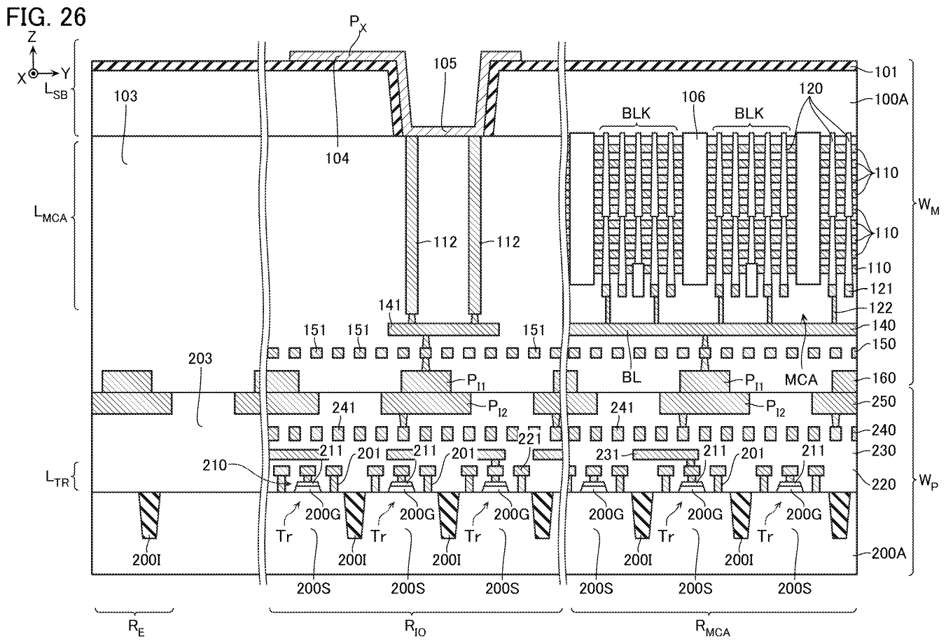

Next, as shown in FIG. 26, for example, the insulating layer 101 and the bonding pad electrode P_{X} are formed on an upper surface of the structure shown in FIG. 25. This step is performed by methods such as CVD and RIE, for example.

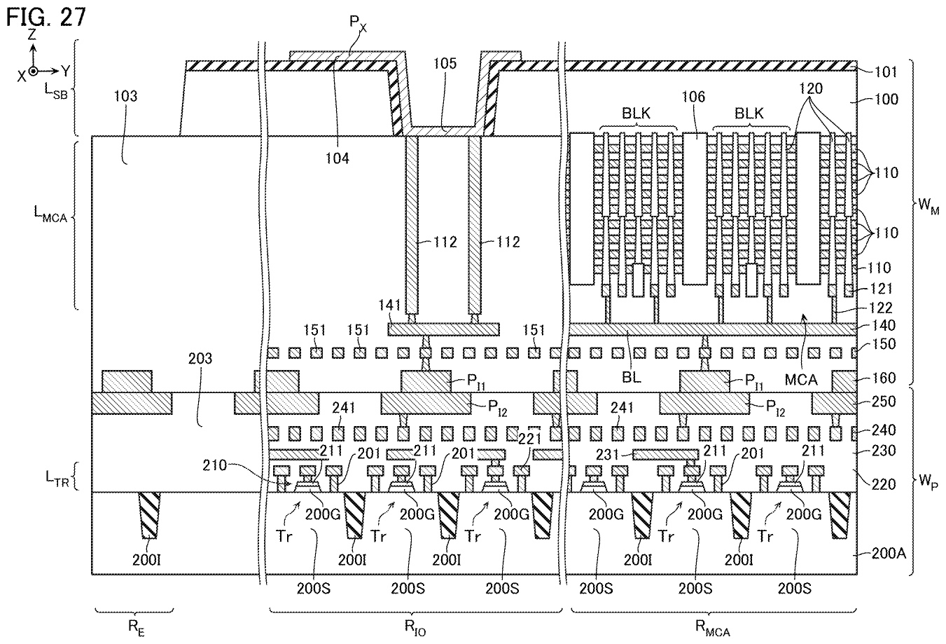

Next, as shown in FIG. 27, for example, part of the semiconductor substrate 100A is removed on the dicing line DL and in the edge region R_{E}. As a result, the insulating layer 103 is exposed on the dicing line DL and in the edge region R_{E}. Moreover, the semiconductor substrate 100 is formed. This step is performed by a method such as RIE, for example.

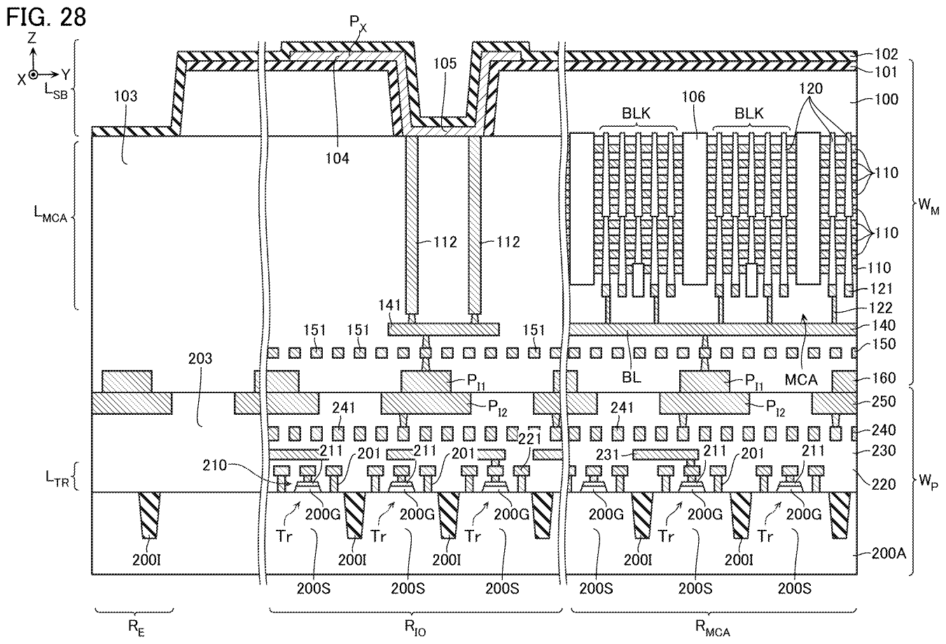

Next, as shown in FIG. 28, for example, the insulating layer 102 is formed on the upper surface of the insulating layer 101, on the upper surface of the bonding pad electrode P_{X}, on the side surfaces in the X direction and the Y direction of the bonding pad electrode P_{X} (including on the inner peripheral surface inside the contact hole), and on the upper surface of the insulating layer 103. This step is performed by a method such as CVD, for example.

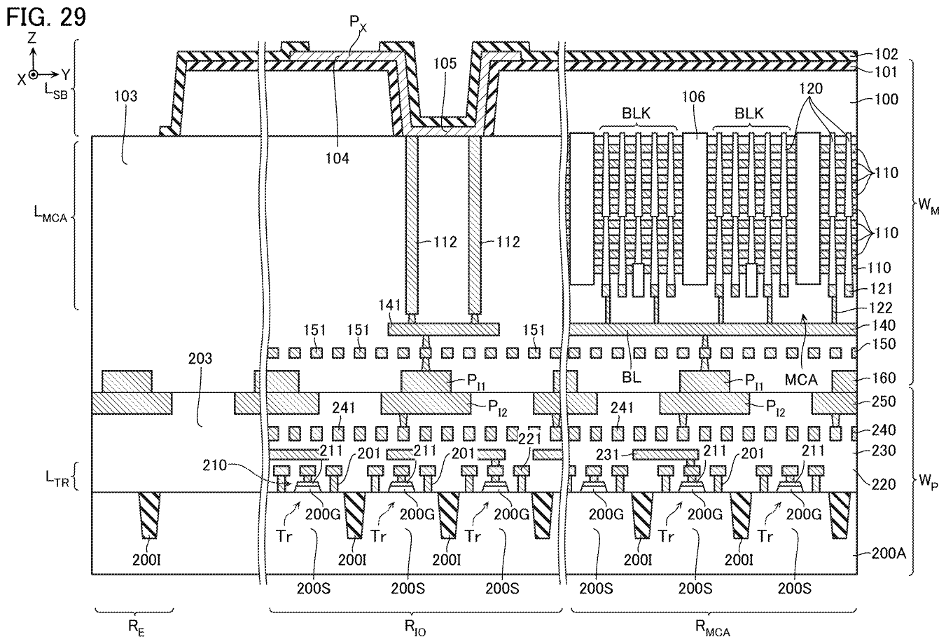

Next, as shown in FIG. 29, for example, part of the insulating layer 102 is removed, whereby part of the external connection region 104 of the bonding pad electrode P_{X} is exposed. This step is performed by a method such as RIE, for example. Note that in this step, the insulating layer 102 may be removed in the edge region R_{E} as illustrated, but need not be so removed.

Next, as described with reference to FIGS. 20 and 21, for example, the wafers W_{M}, W_{P} are cut along the dicing line DL.

The method of manufacturing a semiconductor memory device according to the second embodiment makes it possible for occurrence of a crack or film-peeling, and so on, to be more suitably suppressed compared to in the method of manufacturing according to the comparative example, similarly to in the first embodiment.

Moreover, in the method of manufacturing a semiconductor memory device according to the second embodiment, the metal layer M_{E} is not left on the side surfaces in the X direction and the Y direction of the semiconductor substrate 100 when the wafers W_{M}, W_{P} are cut along the dicing line DL. Hence, the dicing line DL and the edge region R_{E} can be made comparatively small. As a result, the number of memory dies MD manufacturable from one wafer can be increased, and manufacturing costs can thereby be reduced.

### Third Embodiment

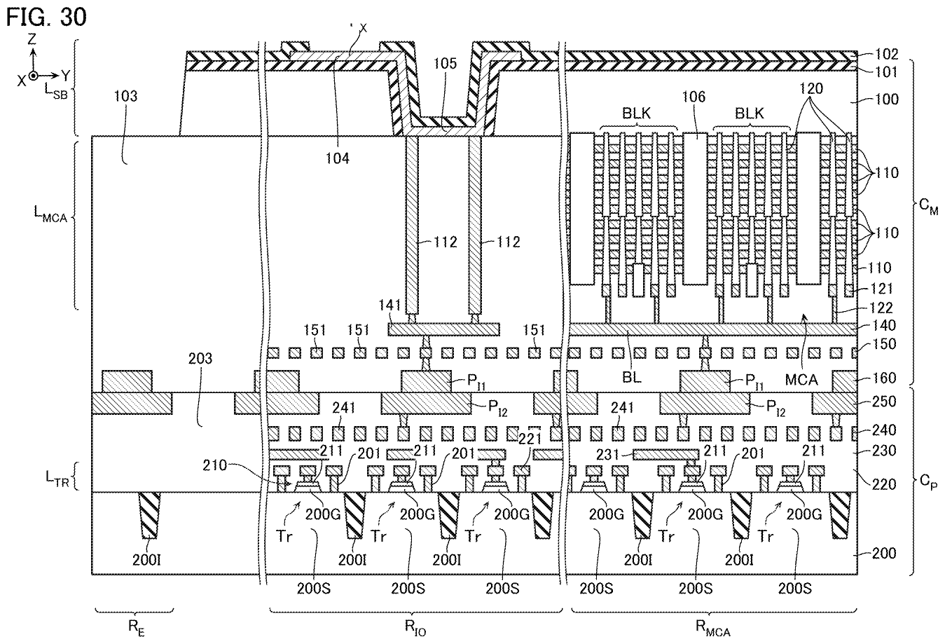

Next, a configuration of a semiconductor memory device according to a third embodiment will be described with reference to FIG. 30. FIG. 30 is a schematic cross-sectional view showing a configuration of part of the semiconductor memory device according to the third embodiment.

The semiconductor memory device according to the third embodiment is basically configured similarly to the semiconductor memory device according to the second embodiment. However, as described with reference to FIG. 24, in the second embodiment, the side surfaces in the X direction and the Y direction of the semiconductor substrate 100 were covered by the insulating layer 102. On the other hand, as shown in FIG. 30, in the third embodiment, the side surfaces in the X direction and the Y direction of the semiconductor substrate 100 are not covered by the insulating layer 102.

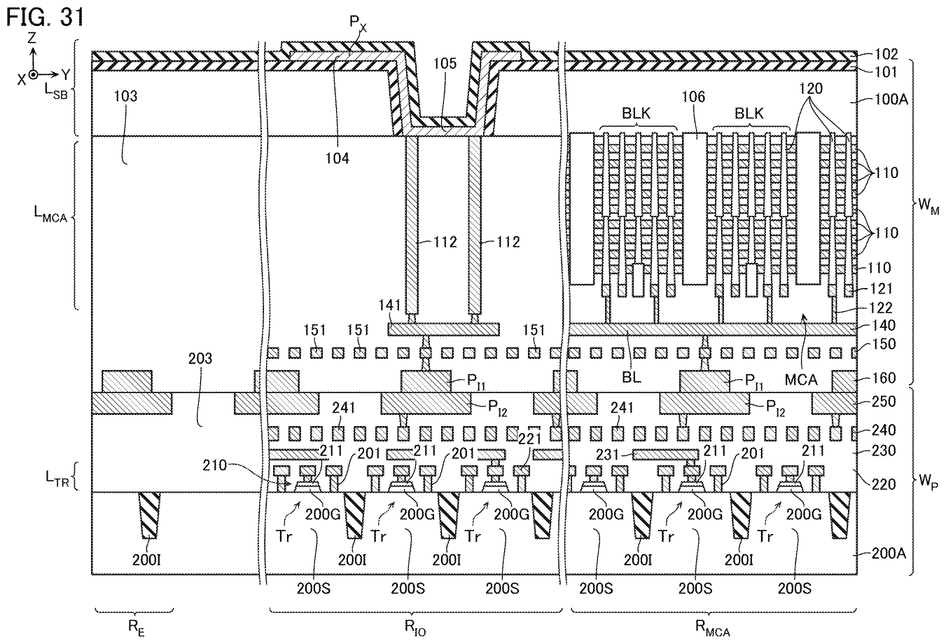

Next, a method of manufacturing a semiconductor memory device according to the third embodiment will be described with reference to FIGS. 31 to 33. FIGS. 31 to 33 are schematic cross-sectional views for explaining same method of manufacturing.

In the method of manufacturing a semiconductor memory device according to the third embodiment, steps up to the step described with reference to FIG. 26, of the method of manufacturing a semiconductor memory device according to the second embodiment are executed.

Next, as shown in FIG. 31, for example, the insulating layer 102 is formed on the upper surface of the insulating layer 101, on the upper surface of the bonding pad electrode P_{X}, on the side surfaces in the X direction and the Y direction of the bonding pad electrode P_{X} (including on the inner peripheral surface inside the contact hole), and on the upper surface of the insulating layer 103. This step is performed by a method such as CVD, for example.

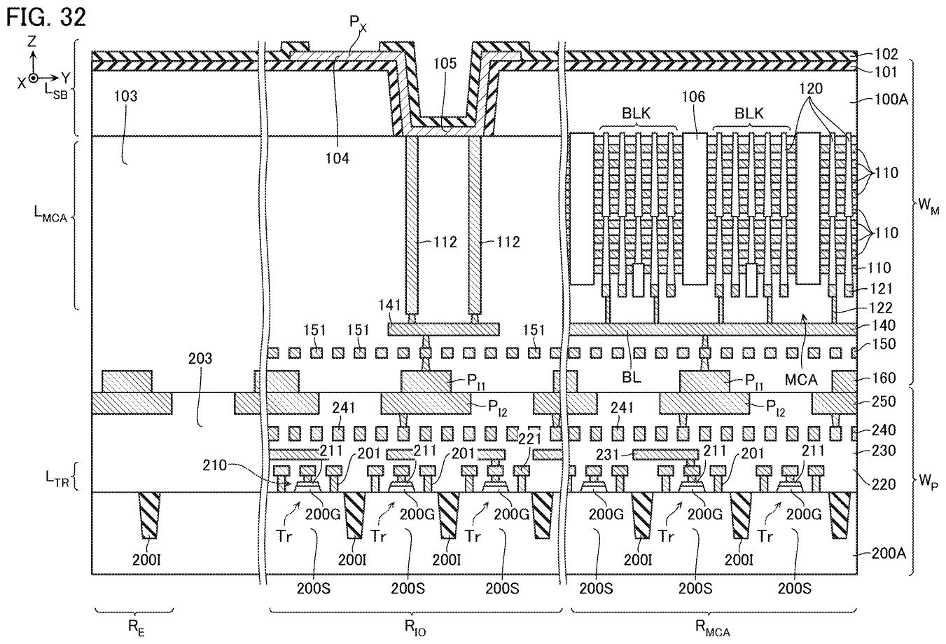

Next, as shown in FIG. 32, for example, part of the insulating layer 102 is removed, whereby part of the external connection region 104 of the bonding pad electrode P_{X} is exposed. This step is performed by a method such as RIE, for example.

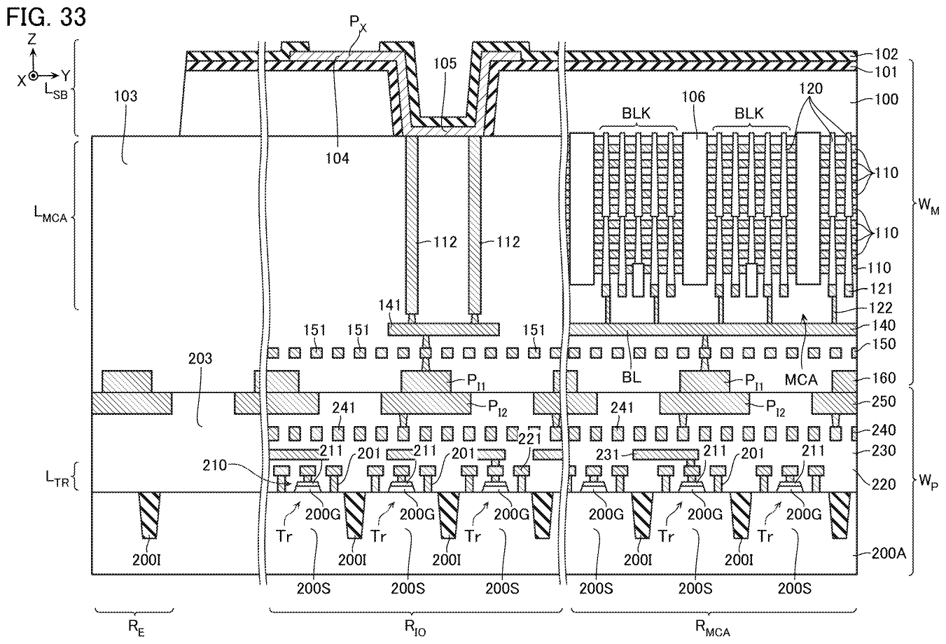

Next, as shown in FIG. 33, for example, part of the semiconductor substrate 100A is removed on the dicing line DL and in the edge region R_{E}. As a result, the insulating layer 103 is exposed on the dicing line DL and in the edge region R_{E}. Moreover, the semiconductor substrate 100 is formed. This step is performed by a method such as RIE, for example.

Next, as described with reference to FIGS. 20 and 21, for example, the wafers W_{M}, W_{P} are cut along the dicing line DL.

The method of manufacturing a semiconductor memory device according to the third embodiment makes it possible for occurrence of a crack or film-peeling, and so on, to be more suitably suppressed compared to in the method of manufacturing according to the comparative example, similarly to in the first embodiment.

Moreover, the method of manufacturing a semiconductor memory device according to the third embodiment makes it possible for manufacturing costs to be reduced, similarly to in the second embodiment.

### Other Embodiments

That concludes description of the semiconductor memory devices and methods of manufacturing the same according to the first through third embodiments. However, the semiconductor memory devices according to these embodiments are merely exemplifications, and specific configurations, methods, and so on, thereof may be appropriately adjusted.

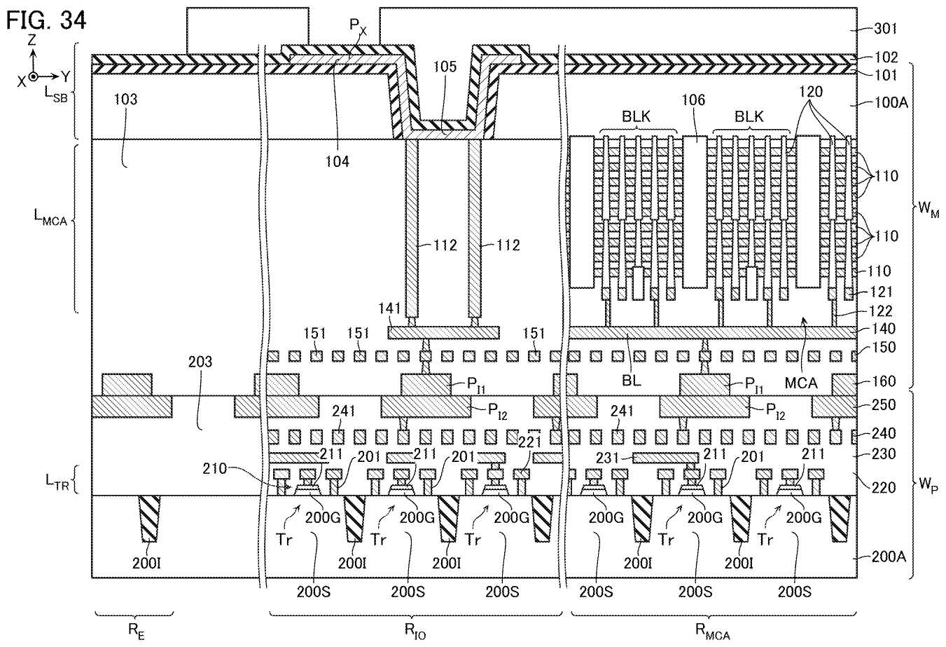

For example, in the method of manufacturing according to the third embodiment, as described with reference to FIGS. 32 and 33, the step of removing part of the insulating layer 102 to expose the bonding pad electrode P_{X} and the step of removing part of the semiconductor substrate 100A on the dicing line DL and in the edge region R_{E} were separately performed. However, such a method is merely an exemplification, and a specific method may be appropriately adjusted. For example, in the method of manufacturing according to the third embodiment, as shown in FIG. 34, for example, the structure shown in FIG. 31 subsequent to execution of the step described with reference to FIG. 31 may have a resist 301 formed on its upper surface. The resist 301 is provided with an opening at a position thereof corresponding to the external connection region 104 of the bonding pad electrode P_{X}, for example. Moreover, the resist 301 is provided with openings at positions thereof corresponding to the dicing line DL and the edge region R_{E}, for example. In such a state, it is possible too for part of the insulating layer 102 and part of the semiconductor substrate 100A to be removed in one step by a method such as RIE, and for a structure of the kind described with reference to FIG. 33 to be formed. In such a case, the method such as RIE is executed under conditions of the semiconductor substrate 100A being more readily removed than the bonding pad electrode P_{X}, for example.

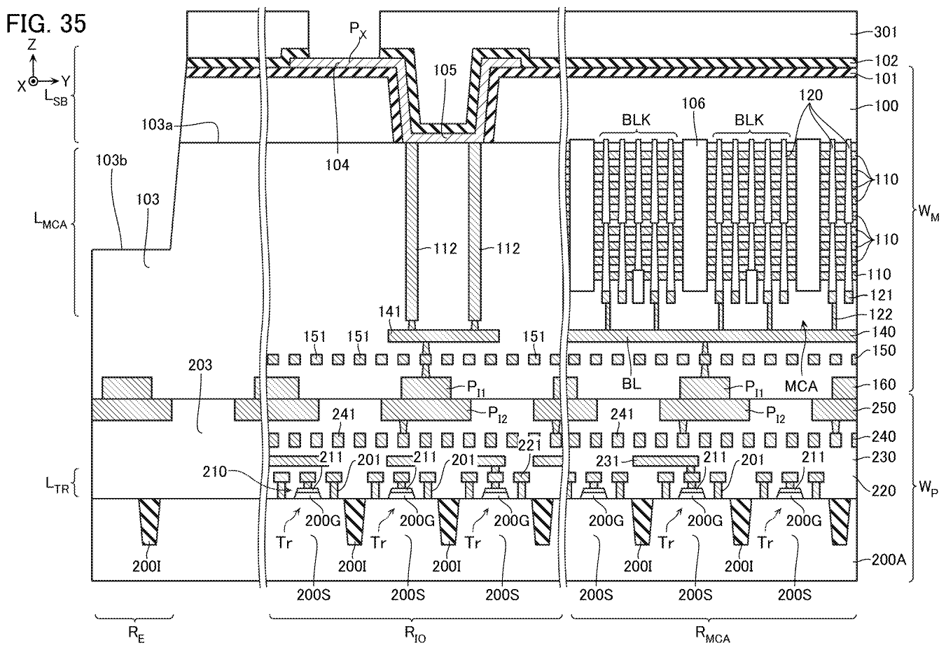

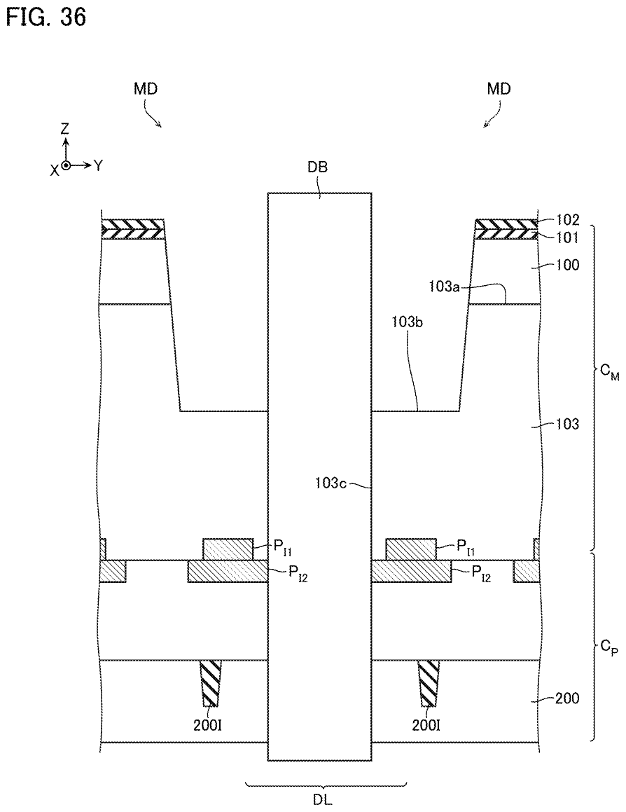

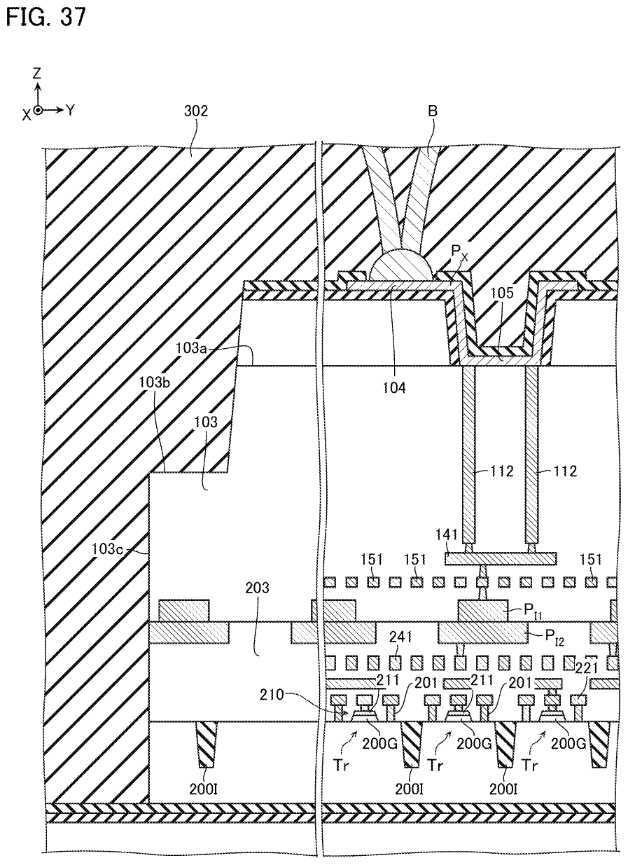

Note that when such a method is executed, sometimes, as shown in FIG. 35, for example, at least part of a portion provided on the dicing line DL and in the edge region R_{E}, of the insulating layer 103 is removed. As a result, a surface 103b positioned more downwardly than a contact surface 103a with the semiconductor substrate 100, is formed in the upper surface of the insulating layer 103. In such a case, as shown in FIG. 36, for example, sometimes, when the wafers W_{M}, W_{P} are cut along the dicing line DL, the surface 103b is left unremoved on the upper surface of the insulating layer 103. When the memory system 10 (FIGS. 2 and 3) is manufactured by such a method, it results in the surface 103a contacting the semiconductor substrate 100, and the surface 103b contacting a mold resin 302, as shown in FIG. 37, for example.

Note that a roughness of the surfaces 103a, 103b of the insulating layer 103 will sometimes be smaller than a roughness of side surfaces 103c in the X direction and the Y direction (for example, surfaces cut by the dicing blade DB) of the insulating layer 103.

Moreover, the mold resin 302 may be an insulating layer of the likes of a polyimide or an epoxy resin, for example. Moreover, the mold resin 302 may include a filler. Moreover, the bonding pad electrode P_{X} of the structures shown in FIGS. 7, 24, and 30 may be connected with the bonding wire B in a form similar to in FIG. 37, although illustration of this is omitted in these drawings. Moreover, an upper surface and side surfaces in the X direction and the Y direction of the structures shown in these drawings may contact the mold resin 302.

Moreover, in the methods of manufacturing according to the first through third embodiments, for example, during dicing of the wafers W_{M}, W_{P}, the wafers W_{M}, W_{P} were cut by the dicing blade DB, as described with reference to FIGS. 20 and 21, for example. However, such a method is merely an exemplification, and a specific method may be appropriately adjusted.

For example, it is conceivable too for a laser to be utilized during dicing of the wafers W_{M}, W_{P}. For example, it is conceivable for parts of configurations in the wafers W_{M}, W_{P} to be removed along the dicing line DL by the laser, and for cutting by the dicing blade DB to be subsequently performed. Moreover, it is conceivable too for damage to be caused to the configurations in the wafers W_{M}, W_{P} along the dicing line DL by the laser, and for the wafers W_{M}, W_{P} to be diced not by a dicing blade, but by a mechanical adaptive force.

Now, in the case of such a method employing a laser being adopted, there will be required a step in which one of the semiconductor substrates 100A, 200A is priorly removed along the dicing line DL. It is possible too for this step to be executed by a similar method to in the methods of manufacturing according to the first through third embodiments. In other words, in the methods of manufacturing according to the first through third embodiments, the above-mentioned kind of method employing a laser may be adopted instead of the step of the kind exemplified in FIGS. 20 and 21.

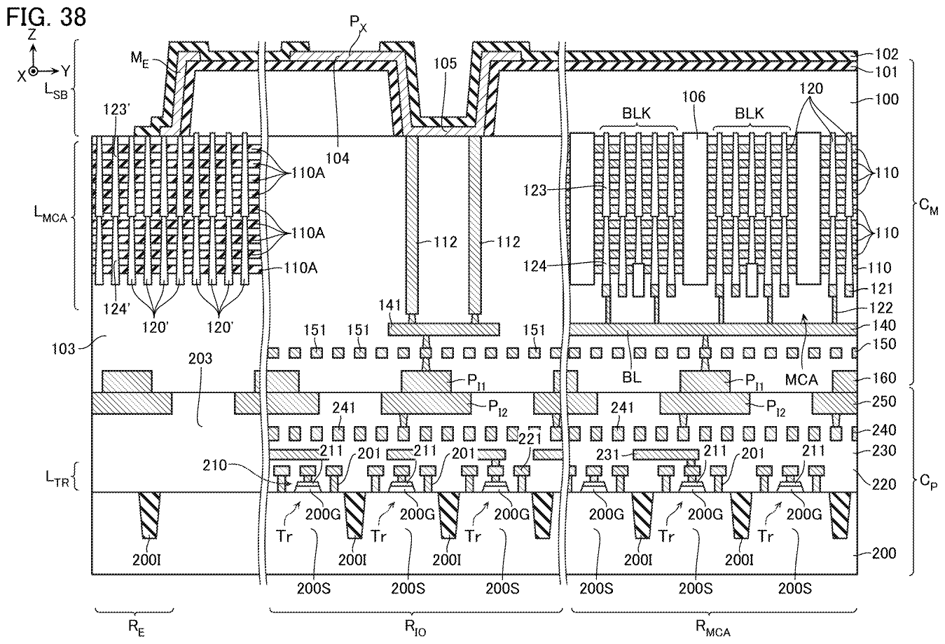

Moreover, in the semiconductor memory devices according to the first through third embodiments, the edge region R_{E} of the memory cell array layer L_{MCA} may be provided with the insulating layer 103 alone, as shown in FIG. 7, for example. Moreover, the edge region R_{E} of the memory cell array layer L_{MCA} may be provided with a plurality of insulating layers 110A or plurality of semiconductor layers and with a plurality of structures 120′ penetrating these insulating layers 110A or semiconductor layers, as shown in FIG. 38, for example.

The plurality of insulating layers 110A or plurality of semiconductor layers are arranged in the Z direction correspondingly to the plurality of conductive layers 110, for example. Moreover, these plurality of insulating layers 110A may include the likes of silicon nitride (Si₃N₄), for example. Moreover, these plurality of semiconductor layers may include the likes of silicon (Si), for example. Moreover, an insulating layer of the likes of silicon oxide (SiO₂), for example, may be provided between these plurality of insulating layers 110A or plurality of semiconductor layers.

The structure 120′ has a substantially circular columnar shape, for example. Moreover, an outer peripheral surface of the structure 120′ is surrounded by respective ones of the plurality of insulating layers 110A or plurality of semiconductor layers, and faces the plurality of insulating layers 110A or plurality of semiconductor layers. An upper end portion of the structure 120′ is connected to the semiconductor substrate 100. The structure 120′ may include the likes of silicon oxide (SiO₂), may include the likes of silicon (Si), or may include another material, for example.

Note that the structure 120′ exemplified in FIG. 38 comprises: a portion 123′ facing approximately that half of the insulating layers 110A or semiconductor layers provided on an upper side; and a portion 124′ facing approximately that half of the insulating layers 110A or semiconductor layers provided on a lower side. Widths in the X direction and the Y direction of an upper end portion of the portion 123′ are smaller than widths in the X direction and the Y direction of a lower end portion of the portion 123′. Moreover, widths in the X direction and the Y direction of an upper end portion of the portion 124′ are smaller than widths in the X direction and the Y direction of a lower end portion of the portion 124′. Moreover, widths in the X direction and the Y direction of the upper end portion of the portion 124′ are smaller than widths in the X direction and the Y direction of the lower end portion of the portion 123′.

Moreover, in the first through third embodiments, a semiconductor memory device was exemplified as an aspect of the semiconductor device. However, it is possible for the configurations and methods of manufacturing of the kind exemplified in the first through third embodiments to be applied also to a semiconductor device other than a semiconductor memory device. As examples of such a semiconductor device, there may be cited the likes of an image sensor, sound sensor, or other sensor, a CPU (Central Processing Unit), GPU (Graphic Processing Unit), FPGA (Field Programmable Gate Array), or other arithmetic device, or a communication circuit, for example.

Moreover, in the first through third embodiments, a semiconductor substrate was exemplified as the substrate included in the two chips C_{M}, C_{P}. However, the substrate included in the two chips to be bonded may be a substrate other than a semiconductor substrate.

### OTHERS

While certain embodiments have been described, these embodiments have been presented byway of example only, and are not intended to limit the scope of the inventions. Indeed, the novel methods and systems described herein may be embodied in a variety of other forms: furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor device comprising
a first chip and a second chip bonded via a plurality of bonding electrodes,
the first chip comprising:
a first substrate;
a first semiconductor element; and
a first bonding electrode which is one of the plurality of bonding electrodes and is electrically connected to the first semiconductor element,
the second chip comprising:
a second substrate;
a second semiconductor element; and
a second bonding electrode which is one of the plurality of bonding electrodes and is electrically connected to the second semiconductor element,
the second substrate comprising:
a pair of first regions which are provided in both end portions in a first direction and extend in a second direction intersecting with the first direction; and
a pair of second regions which are provided in both end portions in the second direction and extend in the first direction, and
viewed from a third direction intersecting with a surface of the second substrate, portions provided in the first region and the second region of the second substrate not overlapping the first substrate.

2. The semiconductor device according to claim 1, wherein
the first semiconductor element is a memory cell capable of storing data.

3. The semiconductor device according to claim 1, wherein
the first semiconductor element comprises:
a plurality of first conductive layers arranged in the third direction;
a first semiconductor layer extending in the third direction and being opposed to the plurality of first conductive layers; and
a first gate insulating layer provided between the plurality of first conductive layers and the first semiconductor layer,
the first semiconductor layer comprises:
a first end portion in the third direction; and
a second end portion which is further from the first bonding electrode than the first end portion is in the third direction, and
widths in the first direction and the second direction of the first end portion are larger than widths in the first direction and the second direction of the second end portion.

4. The semiconductor device according to claim 3, wherein
the first semiconductor element comprises:
a plurality of second conductive layers arranged in the third direction, separated from the plurality of first conductive layers in the third direction;
a second semiconductor layer extending in the third direction and being opposed to the plurality of second conductive layers; and
a second gate insulating layer provided between the plurality of second conductive layers and the second semiconductor layer,
the second semiconductor layer comprises:
a third end portion in the third direction; and
a fourth end portion which is further from the first bonding electrode than the third end portion is in the third direction, and
widths in the first direction and the second direction of the third end portion are larger than widths in the first direction and the second direction of the fourth end portion.

5. The semiconductor device according to claim 1, wherein
a width in the third direction of the first chip is smaller than a width in the third direction of the second chip.

6. The semiconductor device according to claim 1, wherein
an end portion in at least one of the first direction and the second direction of the first substrate is provided with a stacked structure configured from at least one insulating layer and at least one metal layer.

7. A semiconductor device comprising
a first chip and a second chip bonded via a plurality of bonding electrodes,
the first chip comprising:
a first substrate;
a first semiconductor element; and
a first bonding electrode which is one of the plurality of bonding electrodes and is electrically connected to the first semiconductor element,
the second chip comprising:
a second substrate;
a second semiconductor element; and
a second bonding electrode which is one of the plurality of bonding electrodes and is electrically connected to the second semiconductor element, and
when a roughness of at least one end portion in at least one of a first direction and a second direction intersecting with the first direction, of the first substrate is assumed to be a first roughness, and
a roughness of at least one end portion in at least one of the first direction and the second direction of the second substrate is assumed to be a second roughness,
the first roughness being smaller than the second roughness.

8. The semiconductor device according to claim 7, wherein
the first semiconductor element is a memory cell capable of storing data.

9. The semiconductor device according to claim 7, wherein
the first semiconductor element comprises:
a plurality of first conductive layers arranged in a third direction intersecting with the first direction and the second direction;
a first semiconductor layer extending in the third direction and being opposed to the plurality of first conductive layers; and
a first gate insulating layer provided between the plurality of first conductive layers and the first semiconductor layer,
the first semiconductor layer comprises:
a first end portion in the third direction; and
a second end portion which is further from the first bonding electrode than the first end portion is in the third direction, and
widths in the first direction and the second direction of the first end portion are larger than widths in the first direction and the second direction of the second end portion.

10. The semiconductor device according to claim 9, wherein
the first semiconductor element comprises:
a plurality of second conductive layers arranged in the third direction, separated from the plurality of first conductive layers in the third direction;
a second semiconductor layer extending in the third direction and being opposed to the plurality of second conductive layers; and
a second gate insulating layer provided between the plurality of second conductive layers and the second semiconductor layer,
the second semiconductor layer comprises:
a third end portion in the third direction; and
a fourth end portion which is further from the first bonding electrode than the third end portion is in the third direction, and
widths in the first direction and the second direction of the third end portion are larger than widths in the first direction and the second direction of the fourth end portion.

11. The semiconductor device according to claim 7, wherein
a width in a third direction intersecting with the first direction and the second direction of the first chip is smaller than a width in the third direction of the second chip.

12. The semiconductor device according to claim 7, wherein
an end portion in at least one of the first direction and the second direction of the first substrate is provided with a stacked structure configured from at least one insulating layer and at least one metal layer.

13. A method of manufacturing a semiconductor device, comprising the steps of:
bonding a first wafer and a second wafer, the first wafer comprising a first substrate, and the second wafer comprising a second substrate;
removing a portion provided on a dicing line, of the first substrate and thereby dividing the first substrate into a plurality of portions corresponding to a plurality of dies; and
dividing the first wafer and the second wafer along the dicing line and thereby forming the plurality of dies.

14. The method of manufacturing according to claim 13, further comprising the steps of:
when dividing the first substrate into a plurality of portions corresponding to a plurality of dies, forming a plurality of contact holes in the first substrate; and
after forming the plurality of contact holes, but before forming the plurality of dies, forming electrodes on insides of the plurality of contact holes.

15. The method of manufacturing according to claim 13, wherein
the step of dividing the first substrate into a plurality of portions corresponding to a plurality of dies is performed by reactive ion etching, and
the step of dividing the first wafer and the second wafer along the dicing line is performed by blade dicing.

16. The method of manufacturing according to claim 13, wherein
the step of dividing the first substrate into a plurality of portions corresponding to a plurality of dies is performed by reactive ion etching, and
the step of dividing the first wafer and the second wafer along the dicing line is performed by laser dicing.

17. The method of manufacturing according to claim 13, wherein
each of the plurality of dies comprises a first chip and a second chip bonded via a plurality of bonding electrodes,
the first chip comprises:
part of the first substrate;
a first semiconductor element; and
a first bonding electrode which is one of the plurality of bonding electrodes and is electrically connected to the first semiconductor element,
the second chip comprises:
part of the second substrate;
a second semiconductor element; and
a second bonding electrode which is one of the plurality of bonding electrodes and is electrically connected to the second semiconductor element,
the second substrate comprises:
a pair of first regions which are provided in both end portions in a first direction and extend in a second direction intersecting with the first direction; and
a pair of second regions which are provided in both end portions in the second direction and extend in the first direction, and
viewed from a third direction intersecting with a surface of the second substrate, portions provided in the first region and the second region of the second substrate do not overlap the first substrate.

18. The method of manufacturing according to claim 17, wherein
the first semiconductor element is a memory cell capable of storing data.

19. The method of manufacturing according to claim 17, wherein
the first semiconductor element comprises:
a plurality of first conductive layers arranged in the third direction;
a first semiconductor layer extending in the third direction and being opposed to the plurality of first conductive layers; and
a first gate insulating layer provided between the plurality of first conductive layers and the first semiconductor layer,
the first semiconductor layer comprises:
a first end portion in the third direction; and
a second end portion which is further from the first bonding electrode than the first end portion is in the third direction, and
widths in the first direction and the second direction of the first end portion are larger than widths in the first direction and the second direction of the second end portion.

20. The method of manufacturing according to claim 17, wherein
a width in the third direction of the first chip is smaller than a width in the third direction of the second chip.
